(19) United States
(12) Patent Application Publication
(10) Pub. No.: US 2026/0333670 A1
(43) Pub. Date: Oct. 22, 2026

(54) SEMICONDUCTOR DEVICE HAVING BIT LINE STRUCTURE AND METHOD FOR MANUFACTURING THE SAME

(71) Applicant: NANYA TECHNOLOGY CORPORATION, NEW TAIPEI CITY (TW)

(72) Inventor: CHUN-HENG WU, NEW TAIPEI CITY (TW)

(21) Appl. No.: 19/185,529

(22) Filed: Apr. 22, 2025

(51) Int. Cl. H10B 12/00

(52) U.S. Cl. CPC H10B 12/482; H10B 12/02

(57) ABSTRACT

A semiconductor device and a method of manufacturing a semiconductor device are provided. The semiconductor device includes a substrate having a first recess region, a first bit line structure in the first recess region, and an isolation structure within a trench in the substrate. The first bit line structure has a first spacer, a second spacer, and a third spacer. The isolation structure includes a lining layer, an epitaxial layer, a lower insulating structure, and an upper insulating structure.

### TECHNICAL FIELD

The present disclosure relates to a semiconductor device and a method for manufacturing a semiconductor device, and more particularly, to a bit line structure having a spacer.

### DISCUSSION OF THE BACKGROUND

In a semiconductor device, a storage node contact is formed between neighboring bit line structures. In a conventional process, a recess region is created adjacent to a bit line structure, which is then filled with a material of the storage node. However, the formation of the recess region can consume the space of the bit line structure, increasing the risk of leakage between the bit line structure and the storage node contact. This leakage can lead to performance deterioration in the semiconductor device and poses a significant challenge that must be addressed to enhance semiconductor device integration.

As semiconductor devices become more highly integrated, distances between the bit line structures and between the bit line structures and the storage node contacts are diminishing. This reduction in distance may increase the likelihood of a significant parasitic capacitance issue.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device includes a substrate having a first recess region; a first bit line structure disposed in the first recess region; and an isolation structure disposed within a trench in the substrate. The first bit line structure has a first spacer, a second spacer, and a third spacer. The isolation structure includes a lining layer, an epitaxial layer, a lower insulating structure, and an upper insulating structure.

Another aspect of the present disclosure provides a semiconductor device. The semiconductor device includes a substrate having a first recess region; and a first bit line structure disposed in the first recess region. The first bit line structure has a first spacer, an air gap, a second spacer, and a third spacer. The first spacer, the second spacer, and the third spacer have different materials.

Another aspect of the present disclosure provides a method for fabricating a semiconductor device. The method includes forming a trench at a top surface of a substrate, wherein an active area is defined in the substrate laterally surrounded by the trench; performing an oxidation process to form an oxide layer extending along a bottom surface and a sidewall of the trench, wherein an oxidation depth at a top edge of the active area is greater than an oxidation depth at the sidewall and the bottom surface of the trench; filling the trench with an additional insulating material after performing the oxidation process; removing an upper portion of the oxide layer covering the top edge of the active area, and forming an epitaxial layer to cover the top edge of the active area; and filling the trench with an insulating material.

Another aspect of the present disclosure provides a method for fabricating a semiconductor device. The method includes forming a bit line structure on a top surface of a substrate; forming a spacer structure on the bit line structure, the spacer structure including a sacrificial layer sandwiched by a first dielectric layer and a second dielectric layer; removing the sacrificial layer to form a gap between the first dielectric layer and the second dielectric layer; reducing a width of the gap; and forming a seal layer to seal the gap.

The first spacer can prevent the first bit line structure from being damaged or consumed. Therefore, the bit line structure to storage node contact leakage issue can be addressed. The performance and operational reliability of the semiconductor device can also be improved.

In addition, by using a spacer having a low dielectric constant, the parasitic capacitance issue between the bit line structures and/or between the bit line structure and the storage node contact can be further reduced.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic cross-sectional view of a semiconductor device in accordance with some embodiments of the present disclosure.

FIG. 1B is a schematic cross-sectional view of a semiconductor device in accordance with some embodiments of the present disclosure.

FIG. 1C is a schematic cross-sectional view of a semiconductor device in accordance with some embodiments of the present disclosure.

FIG. 1D is a schematic cross-sectional view of a semiconductor device in accordance with some embodiments of the present disclosure.

FIG. 1E is a schematic cross-sectional view of a semiconductor device in accordance with some embodiments of the present disclosure.

FIG. 2A is a schematic plan view illustrating one or more stages of a method of manufacturing a semiconductor device in accordance with some embodiments of the present disclosure.

FIG. 2B is a schematic cross-sectional view illustrating the semiconductor device taken along an A-A′ line shown in FIG. 2A.

FIG. 2C is a schematic cross-sectional view illustrating the semiconductor device taken along a B-B′ line shown in FIG. 2A.

FIG. 3A is a schematic plan view illustrating one or more stages of a method of manufacturing a semiconductor device in accordance with some embodiments of the present disclosure.

FIG. 3B is a schematic cross-sectional view illustrating the semiconductor device taken along an A-A′ line shown in FIG. 3A.

FIG. 4A is a schematic plan view illustrating one or more stages of a method of manufacturing a semiconductor device in accordance with some embodiments of the present disclosure.

FIG. 4B is a schematic cross-sectional view illustrating the semiconductor device taken along an A-A′ line shown in FIG. 4A.

FIG. 4C is a schematic cross-sectional view illustrating the semiconductor device taken along a B-B′ line shown in FIG. 4A.

FIG. 5A is a schematic cross-sectional view illustrating one or more stages of a method of manufacturing a semiconductor device in accordance with some embodiments of the present disclosure.

FIG. 5B is a schematic cross-sectional view illustrating one or more stages of a method of manufacturing a semiconductor device in accordance with some embodiments of the present disclosure.

FIG. 6A is a schematic cross-sectional view illustrating one or more stages of a method of manufacturing a semiconductor device in accordance with some embodiments of the present disclosure.

FIG. 6B is a schematic cross-sectional view illustrating one or more stages of a method of manufacturing a semiconductor device in accordance with some embodiments of the present disclosure.

FIG. 7A is a schematic cross-sectional view illustrating one or more stages of a method of manufacturing a semiconductor device in accordance with some embodiments of the present disclosure.

FIG. 7B is a schematic cross-sectional view illustrating one or more stages of a method of manufacturing a semiconductor device in accordance with some embodiments of the present disclosure.

FIG. 8A is a schematic cross-sectional view illustrating one or more stages of a method of manufacturing a semiconductor device in accordance with some embodiments of the present disclosure.

FIG. 8B is a schematic cross-sectional view illustrating one or more stages of a method of manufacturing a semiconductor device in accordance with some embodiments of the present disclosure.

FIG. 9A is a schematic cross-sectional view illustrating one or more stages of a method of manufacturing a semiconductor device in accordance with some embodiments of the present disclosure.

FIG. 9B is a schematic cross-sectional view illustrating one or more stages of a method of manufacturing a semiconductor device in accordance with some embodiments of the present disclosure.

FIG. 10A is a schematic cross-sectional view illustrating one or more stages of a method of manufacturing a semiconductor device in accordance with some embodiments of the present disclosure.

FIG. 10B is a schematic cross-sectional view illustrating one or more stages of a method of manufacturing a semiconductor device in accordance with some embodiments of the present disclosure.

FIG. 11 is a schematic cross-sectional view illustrating one or more stages of a method of manufacturing a semiconductor device in accordance with some embodiments of the present disclosure.

FIG. 12 is a schematic cross-sectional view illustrating one or more stages of a method of manufacturing a semiconductor device in accordance with some embodiments of the present disclosure.

FIG. 13 illustrates a flowchart diagram of a method of manufacturing a semiconductor device in accordance with some embodiments of the present disclosure.

FIG. 14A is a schematic cross-sectional view illustrating formation of an isolation structure of a semiconductor device taken along a line C-C′ in FIG. 2A in accordance with various embodiments of the present disclosure.

FIG. 14B is a schematic cross-sectional view illustrating formation of an isolation structure of a semiconductor device taken along a line C-C′ in FIG. 2A in accordance with various embodiments of the present disclosure.

FIG. 14C is a schematic cross-sectional view illustrating formation of an isolation structure of a semiconductor device taken along a line C-C′ in FIG. 2A in accordance with various embodiments of the present disclosure.

FIG. 14D is a schematic cross-sectional view illustrating formation of an isolation structure of a semiconductor device taken along a line C-C′ in FIG. 2A in accordance with various embodiments of the present disclosure.

FIG. 14E is a schematic cross-sectional view illustrating formation of an isolation structure of a semiconductor device taken along a line C-C′ in FIG. 2A in accordance with various embodiments of the present disclosure.

FIG. 14F is a schematic cross-sectional view illustrating formation of an isolation structure of a semiconductor device taken along a line C-C′ in FIG. 2A in accordance with various embodiments of the present disclosure.

FIG. 15 illustrates a flowchart diagram of a method of manufacturing an isolation structure of a semiconductor device in accordance with various embodiments of the present disclosure.

FIG. 16A is a schematic cross-sectional view illustrating formation of an air gap of a semiconductor device taken along a line A-A′ in FIG. 2A in accordance with various embodiments of the present disclosure.

FIG. 16B is a schematic cross-sectional view illustrating formation of an air gap of a semiconductor device taken along a line A-A′ in FIG. 2A in accordance with various embodiments of the present disclosure.

FIG. 16C is a schematic cross-sectional view illustrating formation of an air gap of a semiconductor device taken along a line A-A′ in FIG. 2A in accordance with various embodiments of the present disclosure.

FIG. 16D is a schematic cross-sectional view illustrating formation of an air gap of a semiconductor device taken along a line A-A′ in FIG. 2A in accordance with various embodiments of the present disclosure.

FIG. 16E is a schematic cross-sectional view illustrating formation of an air gap of a semiconductor device taken along a line A-A′ in FIG. 2A in accordance with various embodiments of the present disclosure.

FIG. 16F is a schematic cross-sectional view illustrating formation of an air gap of a semiconductor device taken along a line A-A′ in FIG. 2A in accordance with various embodiments of the present disclosure.

FIG. 16G is a schematic cross-sectional view illustrating formation of an air gap of a semiconductor device taken along a line A-A′ in FIG. 2A in accordance with various embodiments of the present disclosure.

FIG. 17 illustrates a flowchart diagram of a method of manufacturing an air gap of a semiconductor device in accordance with various embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

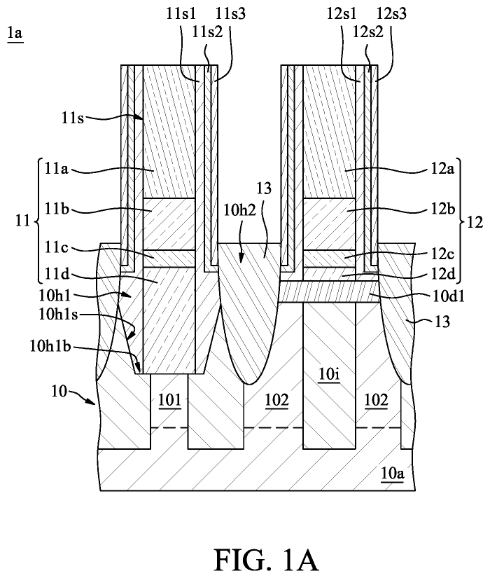

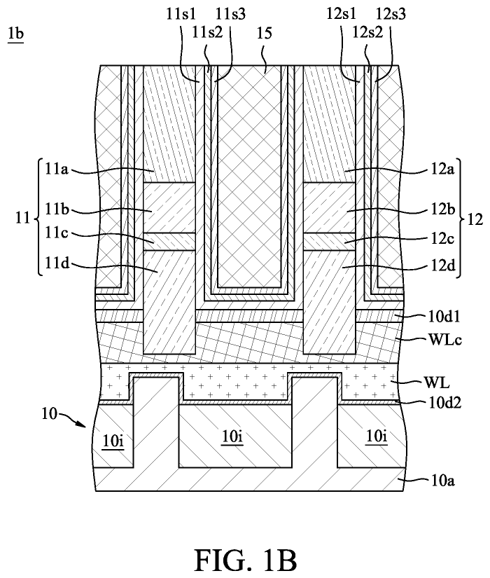

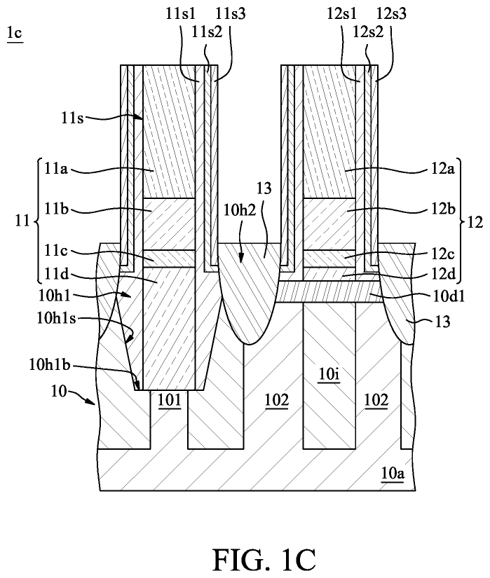

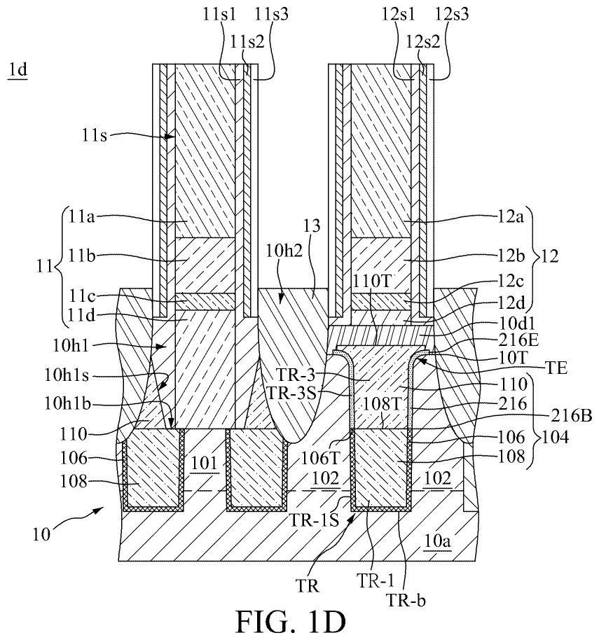

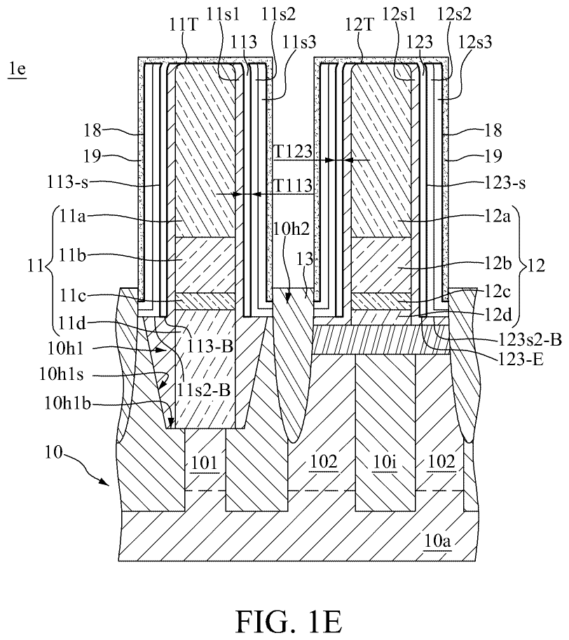

FIG. 1A is a schematic cross-sectional view of a semiconductor device 1a in accordance with some embodiments of the present disclosure. In some embodiments, the semiconductor device 1a may be disposed adjacent to a circuit. For example, the semiconductor device 1a may be disposed adjacent to a memory device such as a dynamic random-access memory (DRAM) device or the like.

Referring to FIG. 1A, the semiconductor device 1a may include a substrate 10 and bit line structures 11 and 12. The bit line structures 11 and 12 may be disposed over the substrate 10.

The substrate 10 may include a substrate. In some embodiments, the substrate 10 may include semiconductor materials such as silicon (Si) in various form, including monocrystalline silicon, polysilicon, and amorphous silicon, as well as germanium (Ge), gallium (Ga), and indium (In). In some embodiments, the substrate 10 may comprise compound semiconductors, including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), and other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

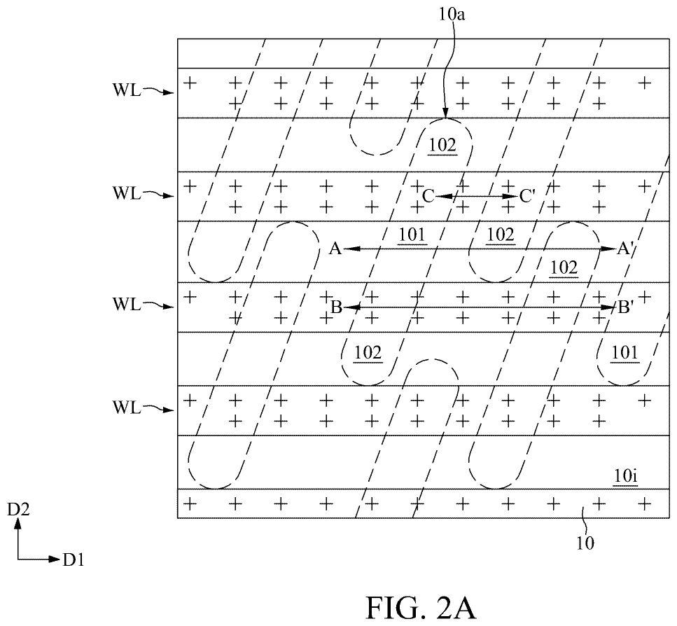

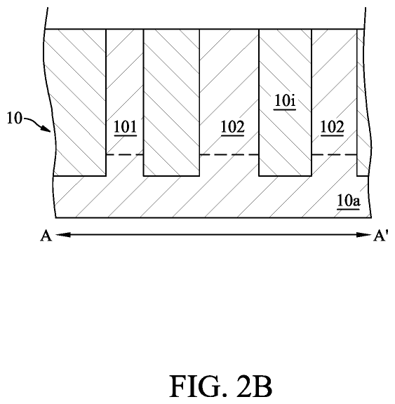

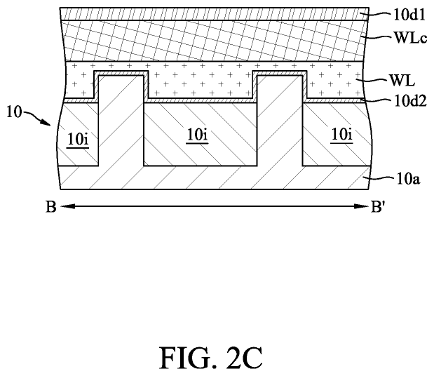

From a cross-sectional view as shown in FIG. 1A, the substrate 10 may include an active region 10a and a plurality of isolation regions 10i. From a top view shown in FIG. 2A, a plurality of the active regions 10a may be defined by the isolation region 10i. For example, a plurality of the active regions 10a may be separated from one another by the isolation region 10i.

The active region 10a and the isolation region 10i may be formed in the substrate 10. In some embodiments, the isolation region 10i may include shallow trench isolation (STI) structures.

A wall oxide, a liner and a gap-fill dielectric may be sequentially formed to create the isolation region 10i. The liner may be formed by stacking silicon oxide (SiO₂) and silicon nitride (Si₃N₄). The gap-fill dielectric may include material such as silicon oxide (SiO₂), silicon nitride (Si₃N₄), and low-k dielectric materials (e.g., those with a dielectric constant less than that of silicon oxide, approximately 3.9), including phosphosilicate glass (PSG), borosilicate glass (BSG), boron-doped phosphosilicate glass (BPSG), undoped silicate glass (USG), etc.), the like, or a combination thereof. In another embodiment, silicon nitride may be used as the gap-fill dielectric in the isolation region 10i.

The substrate 10 may include a plurality of doped regions, such as a first doped region 101 and second doped regions 102. The first doped region 101 and the second doped regions 102 may be formed in the active region 10a. In some embodiments, the first doped region 101 and the second doped regions 102 may be disposed over or proximal to a top surface of the active region 10a. The first doped region 101 and the second doped regions 102 may be spaced apart from each other by the isolation regions 10i. As shown in the top view in FIG. 2A, the first doped region 101 and the second doped region 102 are positioned on opposite sides of one of the word lines WL.

In some embodiments, the first doped region 101 and the second doped region 102 may be doped with an N-type dopant such as phosphorus (P), arsenic (As), or antimony (Sb). In some other embodiments, the first doped region 101 and the second doped region 102 may be doped with a P-type dopant such as boron (B) or indium (In). In some embodiments, the first doped region 101 and the second doped region 102 may be doped with dopants or impurity ions of the same conductivity types. In some embodiments, the first doped region 101 and the second doped region 102 may be doped with dopants or impurity ions of different conductivity types.

Bottom surfaces of the first doped region 101 and the second doped region 102 may be positioned at a predetermined depth from the top surface of the active region 10a. Both the first doped region 101 and the second doped region 102 may be adjacent to sidewalls of the isolation region 10i. In addition, the bottom surfaces of the first doped region 101 and the second doped region 102 may be higher than a bottom surface of the isolation region 10i.

In some embodiments, the first doped region 101 and the second doped region 102 may be referred to as source/drain regions. In some embodiments, the first doped region 101 may include a bit line contact region and may be electrically connected with the bit line structure 11. The second doped region 102 may include a storage node contact region and may be electrically connected with a memory element through the storage node contact 13. In some embodiments, the memory element may be a capacitor, and may include a lower electrode, an upper electrode and a dielectric layer therebetween. In other embodiments, the memory element may be a variable resistance pattern capable of switching between two resistance states by an electrical pulse applied to the memory element. For example, the memory element may include a phase change material capable of changing a crystalline state according to an amount of electrical current, such as perovskite compounds, transition metal oxide, magnetic materials, ferromagnetic materials or antiferromagnetic materials.

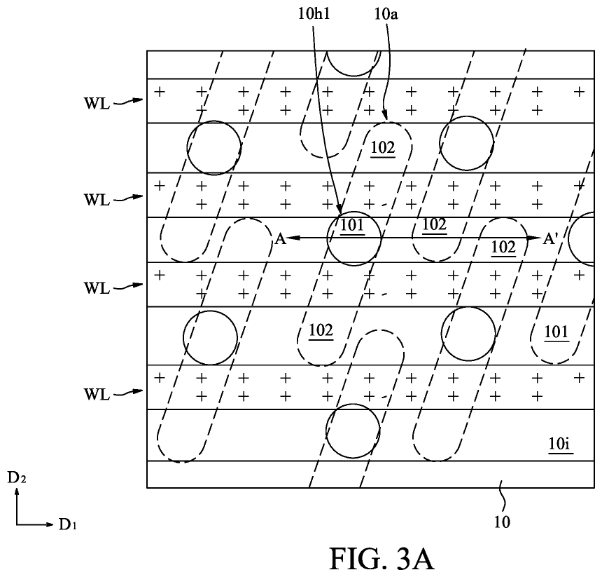

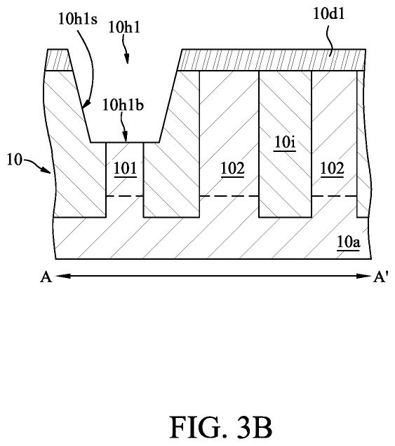

An interlayer 10d1 may be disposed on the substrate 10. The interlayer 10d1 may be disposed on the top surface of the active region 10a. The interlayer 10d1 may be formed of either a single insulating layer or a plurality of insulating layers. The interlayer 10d1 may include an isolating material or a dielectric material. The interlayer 10d1 may include, for example, silicon oxide (SiO₂), silicon nitride (Si₃N₄) and/or silicon oxynitride. The interlayer 10d1 may define the bit line contact region, as shown in FIG. 3B.

A recess region 10h1 may be formed in the substrate 10. The bit line structure 11 may be positioned within the recess region 10h1 and may directly contact the first doped region 101. As a result, the first doped region 101 may serve as the bit line contact region.

The recess region 10h1 may be formed between the isolation regions 10i to expose the first doped region 101 located between the isolation regions 10i. The recess region 10h1 may extend into the substrate 10 from the top surface of the active region 10a and/or from the interlayer 10d1. The recess region 10h1 features a sidewall 10h1s and a bottom surface 10h1b. The sidewall 10h1s may extend from the bottom surface 10h1b to the top surface of the active region 10a and/or the interlayer 10d1.

The sidewall 10h1s of the recess region 10h1 may be inclined in accordance with the top surface of the active region 10a and/or the interlayer 10d1. The recess region 10h1 may narrow or taper toward the interior of the substrate 10. A width of the recess region 10h1 may vary; for example, the width of the recess region 10h1 adjacent to the top surface of the active region 10a may be greater than the width of the recess region 10h1 adjacent to the bottom surface 10h1b. A minimum width of the recess region 10h1 may correspond to the width of the bottom surface 10h1b.

The width of the bottom surface 10h1b of the recess region 10h1 may be greater than a distance between the isolation regions 10i. In some embodiments, the minimum width of the bottom surface 10h1b of the recess region 10h1 may be greater than a width of the bit line structure 11. For example, the bottom surface of the bit line structure 11 may contact the exposed surfaces of the doped region 101 and the isolation regions 10i.

The bottom surface 10h1b of the recess region 10h1 may be positioned higher than the bottom surface of the first doped region 101. For example, the recess region 10h1 may not extend beyond the bottom surface of the first doped region 101.

A recess region 10h2 may be formed in the substrate 10 to expose the second doped region 102. The second doped region 102 may contact the storage node contact 13, thereby serving as the storage node contact region.

The recess region 10h2 may recess from the top surface of the active region 10a and/or from the interlayer 10d1. The recess region 10h2 may be adjacent to the recess region 10h1.

The storage node contact 13 may be formed of a doped polysilicon layer and may penetrate the interlayer 10d1 to directly contact the second doped region 102.

A bottom surface of the storage node contact 13 may be positioned lower than the bottom surface 10h1b of the recess region 10h1.

The bit line structure 11 may include a bit line contact 11d and stacked patterns, such as a conductive pattern 11c, a conductive pattern 11b, and a bit line capping pattern 11a.

The bit line contact 11d may be located in the recess region 10h1, with a portion directly contacting the first doped region 101. A bottom surface of the bit line contact 11d may be positioned lower than the top surface of the active region 10a or lower than the interlayer 10d1. In some embodiments, the bit line contact 11d may consist of a doped polysilicon.

The conductive pattern 11c may include any suitable material, such as titanium (Ti), tantalum (Ta), titanium nitride (TiN), tantalum nitride (TaN), tungsten nitride (W2N, WN, WN2), the like, or a combination thereof.

The conductive pattern 11b may include any suitable metal, such as tungsten (W), copper (Cu), ruthenium (Ru), aluminum (Al), gold (Au), cobalt (Co), the like, or a combination thereof.

The bit line capping pattern 11a may include, for example, silicon oxide (SiO₂), silicon nitride (Si₃N₄) and/or silicon oxynitride.

The bit line structure 11 may include spacers 11s1, 11s2, and 11s3 formed on both sidewalls 11s of the bit line structure 11. The spacers 11s1, 11s2, and 11s3 may also be referred to as a first spacer, a second spacer, and a third spacer. The spacer 11s1 may be disposed between the spacer 11s2 and the sidewalls 11s of the bit line structure 11. For example, the spacer 11s1 may directly contact the sidewalls of the bit line structure 11. The spacer 11s2 may be disposed between the spacer 11s1 and the spacer 11s3. The spacer 11s3 may be the outermost spacer of the bit line structure 11.

The spacers 11s1, 11s2, and 11s3 may be made of different materials. In some embodiments, the spacer 11s1 may consist of a carbon-containing material, such as SiC (silicon carbide), SiOC (silicon oxycarbide), SiCN (silicon carbon nitride), and SiOCN (silicon oxycarbonitride). The spacer 11s2 may composed of an oxygen-containing material, such as silicon oxide (SiO₂). The spacer 11s3 may include a nitrogen-containing material, such as silicon nitride (Si₃N₄).

The spacers 11s1, 11s2, and 11s3 may have different dielectric constants. In some embodiments, the spacer 11s1 may have a first dielectric constant, the spacer 11s2 may have a second dielectric constant, and the spacer 11s3 may have a third dielectric constant.

The first dielectric constant may be lower than the second dielectric constant. The second dielectric constant may be lower than the third dielectric constant. For example, the third dielectric constant may be approximately 7.5, and the second dielectric constant may be less than approximately 7.5. For example, the second dielectric constant may be approximately 3.9, and the first dielectric constant may be less than approximately 3.9. For example, the first dielectric constant may range from approximately 1.0 to 3.9. In some embodiments, the spacer 11s1 may include a low-k material.

The spacer 11s1 may have a thickness of approximately 10 nanometers (nm) or less. In one embodiment, the thickness of the spacer 11s1 may range from approximately 5 nm to approximately 8 nm.

The spacer 11s1 may be continuously disposed on sidewalls of the bit line structure 11. For example, the spacer 11s1 may directly contact the bit line capping pattern 11a, the conductive pattern 11b, the conductive pattern 11c, and the bit line contact 11d. In some embodiments, the spacer 11s1 may be disposed in the recess region 10h1, filling the space between the bit line structure 11 and the substrate 10, as well as the space between the bit line structure 11 and the isolation regions 10i.

The spacer 11s1 may extend between the sidewall 10h1s and the bit line contact 11d. The spacer 11s1 may directly contact the sidewall 10h1s and the bottom surface 10h1b of the recess region 10h1. In some embodiments, only the spacer 11s1 may exist between the sidewall 10h1s and the bit line contact 11d, with no other materials present.

In some embodiments, the storage node contact 13 may truncate the sidewall 10h1s, allowing the spacer 11s1 to directly contact the storage node contact 13.

The bit line structure 12 may be spaced apart from (or separated from) the bit line structure 11 by the storage node contact 13. The bit line structure 12 may be disposed over the interlayer 10d1. The bit line structure 12 may be spaced apart from (or separated from) the substrate 10 by the interlayer 10d1.

The bit line structure 12 may include a bit line contact 12d and stacked patterns, such as a conductive pattern 12c, a conductive pattern 12b, and a bit line capping pattern 12a. In addition, spacers 12s1, 12s2, and 12s3 may be formed on both sidewalls of the bit line structure 12. The detailed descriptions of the bit line structure 12 may refer to detailed descriptions of the bit line structure 11 provided above, which will not be repeated for the sake of brevity.

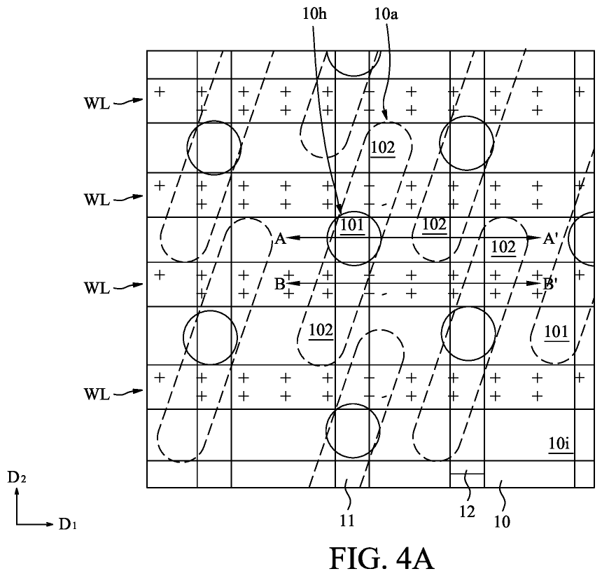

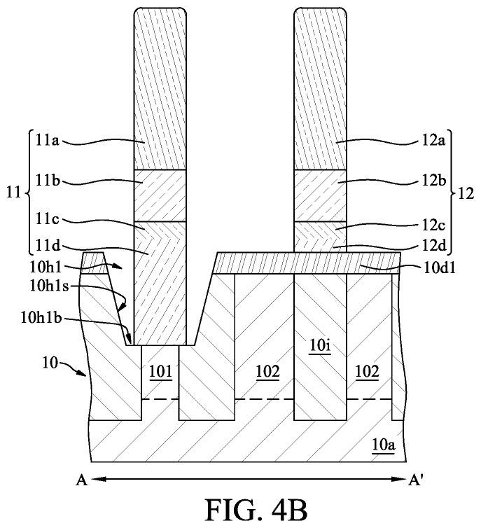

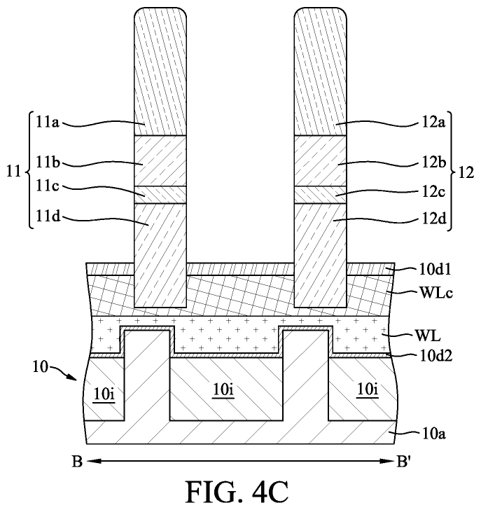

FIG. 1B is a schematic cross-sectional view of a semiconductor device 1b in accordance with some embodiments of the present disclosure. FIG. 1A illustrates a cross-sectional view taken along lines A-A′ of FIG. 4A and FIG. 1B illustrates a cross-sectional view taken along lines B-B′ of FIG. 4A. The semiconductor device 1b of FIG. 1B is similar to the semiconductor device 1a of FIG. 1A, except for the differences described below.

The active region 10a may protrude more than the isolation region 10i. A dielectric layer 10d2 may be conformally formed on the active region 10a and the isolation region 10i.

The word line WL may be disposed over the dielectric layer 10d2. The word line WL may include a gate electrode. The word line WL may extend through the active regions 10a and the isolation region 10i. A capping layer WLc of the word line WL may be disposed on the gate electrode of the word line WL. The capping layer WLc serves to protect the gate electrode of the word line WL.

The bit line contact 11d of the bit line structure 11 may be partially surrounded by the capping layer WLc. The bit line contact 12d of the bit line structure 12 may be partially surrounded by the capping layer WLc.

The spacer 11s1 and the spacer 12s1 may be connected. For example, the spacer 11s1 and the spacer 12s1 may extend between the bit line structure 11 and the bit line structure 12. For example, the carbon-containing materials of the spacer 11s1 and the spacer 12s1 may extend between the bit line structure 11 and the bit line structure 12.

The spacer 11s2 and the spacer 12s2 may be connected. For example, the spacer 11s2 and the spacer 12s2 may extend between the bit line structure 11 and the bit line structure 12. For example, the oxygen-containing materials of the spacer 11s2 and the spacer 12s2 may extend between the bit line structure 11 and the bit line structure 12.

The spacer 11s3 and the spacer 12s3 may be connected. For example, the spacer 11s3 and the spacer 12s3 may extend between the bit line structure 11 and the bit line structure 12. For example, the nitrogen-containing materials of the spacer 11s3 and the spacer 12s3 may extend between the bit line structure 11 and the bit line structure 12.

An insulating pattern 15 may be formed between the bit line structure 11 and the bit line structure 12. For example, the insulating pattern 15 may be disposed over the spacer 11s3 and the spacer 12s3.

FIG. 1C is a schematic cross-sectional view of a semiconductor device 1c in accordance with some embodiments of the present disclosure. The semiconductor device 1c of FIG. 1C is similar to the semiconductor device 1a of FIG. 1A, except that the bottom surface of the storage node contact 13 may be positioned higher than the bottom surface 10h1b of the recess region 10h1 in accordance with the substrate 10. For example, the bottom surface 10h1b of the recess region 10h1 may be positioned lower than the bottom surface of the storage node contact 13 in accordance with the substrate 10. For example, the bottom surface (at the same elevation of the bottom surface 10h1b) of the bit line structure 11 may be positioned lower than the bottom surface of the storage node contact 13 in accordance with the substrate 10.

FIG. 1D is a schematic cross-sectional view of a semiconductor device 1d in accordance with some embodiments of the present disclosure. The semiconductor device 1d in FIG. 1D is similar to the semiconductor device 1a in FIG. 1A. Elements in FIG. 1D that are same as or similar to elements in FIG. 1A are marked with similar reference numbers and duplicative descriptions are omitted.

As shown in FIG. 1D, the semiconductor device 1d may include an isolation structure 104 disposed in a trench TR in the substrate 10a. The trench TR may be located in a place previously occupied by the isolation region 10i in FIG. 1A. The isolation structure 104 may include a lining layer 106, an epitaxial layer 216, a lower insulating structure 108, and an upper insulating structure 110.

In some embodiments, the lining layer 106 may conformally cover a bottom portion TR-b of the trench TR. In some embodiments, the lining layer 106 may be in contact with the epitaxial layer 216 from below the epitaxial layer 216. A lower sidewall TR-1S of a lower part TR-1 of the trench TR is covered by the lining layer 106. In some embodiments, the lining layer 106 is formed of an insulating material, such as silicon oxide.

In some embodiments, the epitaxial layer 216 may be conformally formed on an upper sidewall TR-3S of an upper part TR-3 of the trench TR and on a top edge TE of the active region 10a. In other words, the upper sidewall TR-3S of the upper part TR-3 and the top edge TE of the active region 10a may be conformally covered by the epitaxial layer 216. In some embodiments, the upper sidewall TR-3S may be substantially coplanar with the lower sidewall TR-1S. A topmost end 216E of the epitaxial layer 216 may be slightly higher than a topmost surface 10T of the substrate 10. In some embodiments, the epitaxial layer 216 is formed using an epitaxial process.

In some embodiments, the lower insulating structure 108 is filled in the lower part TR-1 of the trench TR. In some embodiments, the lower insulating structure 108 may be filled to a height 108T substantially leveled with a topmost end 106T of the lining layer 106, which may be in contact with bottommost end of the epitaxial layer 216. The lower insulating structures 108 may be formed of an insulating material. In some embodiments, the lower insulating structures 108 is formed of silicon oxide.

In some embodiments, the upper insulating structure 110 is filled in the upper part TR-3 of the trench TR, and may be in lateral contact with the epitaxial layer 216. In some embodiments, the upper insulating structure 110 extends from a top surface 108T of the lower insulating structure 108 to a top surface 110T of the upper insulating structure 110 substantially higher than the topmost end 216E of the epitaxial layer 216. The upper insulating structures 110 may be formed of an insulating material. In some embodiments, the upper insulating structure 110 is formed of silicon oxide. In some embodiment, the lower insulating structure 108 and the upper insulating structures 110 may be formed of different insulating materials.

FIG. 1E is a schematic cross-sectional view of a semiconductor device 1e in accordance with some embodiments of the present disclosure. The semiconductor device 1e in FIG. 1E is similar to the semiconductor device 1a in FIG. 1A. Elements in FIG. 1E that are same as or similar to elements in FIG. 1A are marked with similar reference numbers and duplicative descriptions are omitted.

As shown in FIG. 1E, the semiconductor device 1e may include an air gap 113, an air gap 123, a spacer layer 18, and a seal layer 19. The air gap 113 may be sandwiched by the spacer 11s1 and the spacer 11s2. In some embodiment, a bottom surface 113-B of the air gap 113 is coplanar with a bottom surface 11s2-B of the spacer 11s2. A width T113 of the air gap 113 is in a range from 3 to 5 nanometers.

The air gap 123 may be sandwiched by the spacer 12s1 and the spacer 12s2. In some embodiment, a bottom surface 123-B of the air gap 123 is coplanar with a bottom surface 12s2-B of the spacer 12s2. A width T123 of the air gap 123 is in a range from 3 to 5 nanometers.

The spacer layer 18 may be formed lining the air gap 113 and the spacer 11s3. The spacer layer 18 may further be formed on top surfaces of the bit line structure 11 and the spacers 11s1 and 11s2. Additionally, the spacer layer 18 may be formed lining the air gap 123 and the spacer 12s3. The spacer layer 18 may also be formed on top surfaces of the bit line structure 12 and the spacers 12s1 and 12s2. It should be noted that the spacer layer 18 is formed with a thickness that depends on the width T113 of the air gap 113 and/or the width T123 of the air gap 123.

The seal layer 19 may be formed over the substrate 10 covering the bit line structures 11 and 12, the spacers 11s1, 11s2, 11s3, 12s1, 12s2 and 12s3, and sealing the air gaps 113 and 123. In some embodiments, the seal layer 19 is formed using a chemical vapor deposition (CVD), which may seal the air gaps 113 and 123 without filling in the second gap 135.

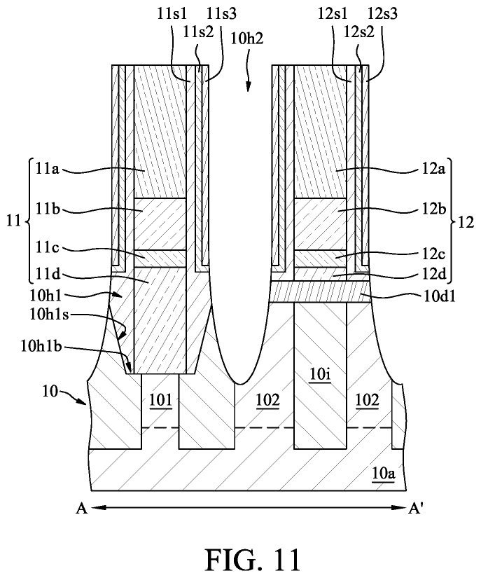

In a conventional process, a recess region (such as the recess region 10h2) may be formed adjacent to a bit line structure (such as the bit line structure 11), and a material of a storage node contact (such as the storage node contact 13) may fill the recess region. A spacer (such as the spacers 11s1, 11s2, and 11s3) of the bit line structure may inevitably be consumed in the operation of forming the recess region (such as the operation in FIG. 11), which in turn may increase the likelihood of a bit line structure to storage node contact leakage issue. Said leakage issue can cause performance deterioration of the semiconductor device, and is a limiting factor that must be addressed to achieve further enhancements in semiconductor device integration.

The first spacer (such as the spacer 11s1) can prevent the first bit line structure (such as the bit line structure 11) from being damaged or consumed. Therefore, the bit line structure to storage node contact leakage issue can be addressed. The performance and operational reliability of the semiconductor device can also be improved.

In addition, by using a spacer (such as the spacer 11s1) having a low dielectric constant, the parasitic capacitance issue between the bit line structures and/or between the bit line structure and the storage node contact can be further decreased.

FIGS. 2A, 2B, 2C, 3A, 3B, 4A, 4B, 4C, 5A, 5B, 6A, 6B, 7A, 7B, 8A, 8B, 9A, 9B, 10A, 10B, 11, and 12 illustrate various stages of a method for manufacturing a semiconductor device in accordance with some embodiments of the present disclosure. Some figures have been simplified for better understanding. In some embodiments, the semiconductor device 1a shown in FIG. 1A may be manufactured through the operations described in the aforementioned figures.

As shown in FIG. 2A, the semiconductor device may include a plurality of active regions 10a. The active regions 10a may be arranged in a zigzag form. For example, the active regions 10a may be arranged in two dimensions along a first direction D1 and a second direction D2 that intersects or crosses (e.g., is perpendicular to) the first direction D1. In some embodiments, the active regions 10a may have a major axis oblique to both the first direction D1 and the second direction D2.

The isolation region 10i may be formed through a shallow trench isolation (STI) process. For example, after a pad layer is formed on the substrate 10, the pad layer and the substrate 10 are etched using an isolation mask to define an isolation trench. The isolation trench is then filled with a dielectric material, resulting in the formation of the isolation region 10i.

The isolation trench may be filled with a dielectric material using a chemical vapor deposition (CVD) process. In some embodiments, a planarization process, such as chemical mechanical polishing (CMP), may be performed.

The semiconductor device may also include a plurality of word lines WL. Each active region 10a may intersect two word lines WL and may be divided into three doped regions by the two word lines WL. For example, the active region 10a may be divided into a first doped region 101 disposed between two word lines WL and second doped regions 102 located on either sides of the first doped region 101.

The word lines WL may each have a line shape extending in a specific direction, such as the first direction D1. The word lines WL may each be a buried gate buried in a trench that runs through the active regions 10a and the isolation region 10i.

FIG. 2B illustrates a cross-sectional view taken along line A-A′ in FIG. 2A, and FIG. 2C illustrates a cross-sectional view taken along line B-B′ in FIG. 2A.

As shown in FIG. 2B, the first doped region 101 and two second doped regions 102 may be formed in the active region 10a. The first doped region 101 and two second doped regions 102 may be spaced apart from one another by the isolation regions 10i. As shown in FIG. 2C, the dielectric layer 10d2 may be disposed between the word line WL and the active region 10a, and between the word line WL and the isolation regions 10i. The active region 10a may protrude into the word line WL and may form a fin structure in accordance with the isolation regions 10i.

As shown in FIG. 3A, one or more recess regions may be formed in the substrate 10. For example, the recess region 10h1 may be formed in the first doped region 101 between two word lines WL. In some embodiments, the substrate 10 may be patterned to form one or more recess regions exposing the first doped region 101. In some embodiments, the substrate 10 may be patterned to form one or more recess regions exposing a bit line contact region in the first doped region 101, which is configured to be electrically connected to a bit line structure.

In some embodiments, form a top view perspective, the recess regions may be arranged in either a honeycomb or zigzag pattern. In some embodiments, the recess regions may each have a circular shape or elliptical shape.

FIG. 3B illustrates a cross-sectional view taken along line A-A′ in FIG. 3A. The interlayer 10d1 may be disposed on the substrate 10 and on a top surface of the active region 10a.

In some embodiments, the recess region 10h1 may be formed by an etching operation, such as an anisotropic etching process. For example, the interlayer 10d1 may define the first doped region 101 or the bit line contact region within the first doped region 101.

In some embodiments, a portion of the isolation regions 10i and a portion of the interlayer 10d1 that are adjacent to the first doped region 101 may be etched together. For example, the sidewall 10h1s may be inclined in accordance with the top surface of the active region 10a and/or the interlayer 10d1. The recess region 10h1 may narrow or taper toward the interior of the substrate 10. In some embodiments, a sidewall of the interlayer 10d1 may be substantially aligned with the sidewall 10h1s.

As shown in FIG. 4A, a plurality of bit line structures, such as bit line structures 11 and 12, may be formed over the substrate 10.

The bit line structures may each have a linear shape extending in a second direction D2 crossing the word lines WL. The bit line structures may each overlap multiple recess regions. For example, the bit line structure 11 may overlap the recess region 10h1.

FIG. 4B illustrates a cross-sectional view taken along line A-A′ in FIG. 4A. FIG. 4C illustrates a cross-sectional view taken along line B-B′ in FIG. 4A.

As shown in FIG. 4B and FIG. 4C, the bit line structure 11 may include the bit line contact 11d for connecting the bit line contact region in the first doped region 101. The bit line structure 12 may include the bit line contact 12d disposed over the interlayer 10d1. Each bit line structure may include a bit line contact, a conductive pattern, and a bit line capping pattern that are sequentially stacked.

In some embodiments, the bit line structure 11 may be formed by depositing a material of the bit line contact 11d over the interlayer 10d1 to fill the recess region 10h1, followed by sequential depositing of materials for the conductive pattern 11c, the conductive pattern 11b, and the bit line capping pattern 11a. The materials may then be etched using a bit line mask pattern.

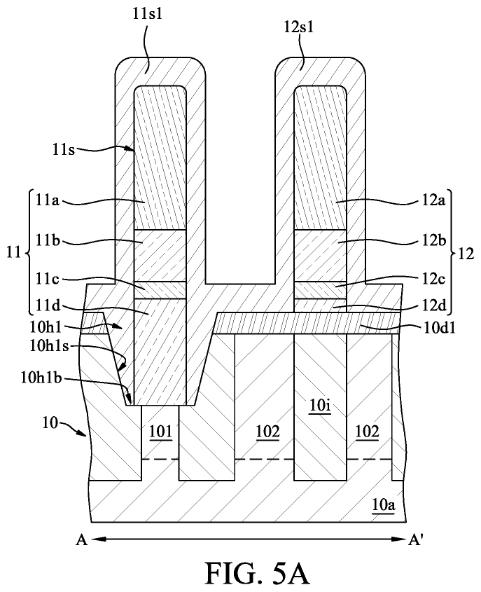

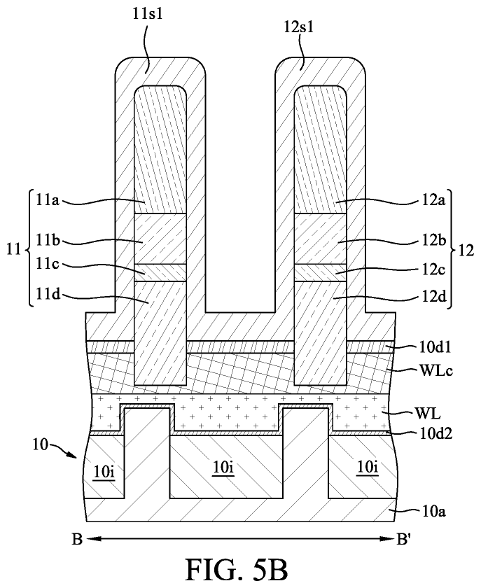

FIG. 5A and FIG. 5B illustrate operations subsequent to the operation in FIG. 4A. FIG. 5A illustrates a cross-sectional view taken along line A-A′ of FIG. 4A. FIG. 5B illustrates a cross-sectional view taken along line B-B′ of FIG. 4A.

As shown in FIG. 5A and FIG. 5B, a material of the spacer 11s1 may be formed on opposite sidewalls 11s of the bit line structure 11. A material of the spacer 12s1 may be formed on opposite sidewalls 11s of the bit line structure 12. In some embodiments, the spacers 11s1 and 12s1 may each include a carbon-containing material, such as SiC (silicon carbide), SiOC (silicon oxycarbide), SiCN (silicon carbon nitride), and SiOCN (silicon oxycarbonitride). In some embodiments, the spacers 11s1 and 12s1 may be formed by any suitable process, such as low-pressure chemical vapor deposition (LPCVD), plasma enhanced-chemical vapor deposition (PECVD), atomic layer deposition (ALD), physical vapor deposition (PVD), or through thermal or chemical grown.

In some embodiments, the materials for the spacers 11s1 and 12s1 may fill the recess region 11h1 and conformally cover the bit line structures 11 and 12.

In some embodiments, a thickness of the material of the spacer 11s1 on the bit line structure 11 may range from approximately 15 nm to approximately 20 nm. In some embodiments, a thickness of the material of the spacer 12s1 on the bit line structure 12 may range from approximately 15 nm to approximately 20 nm.

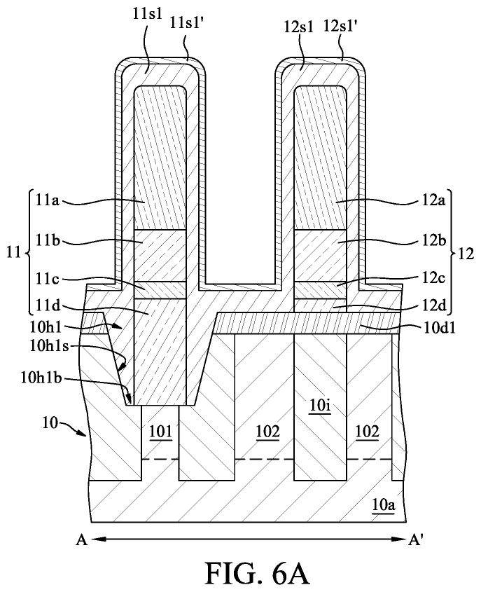

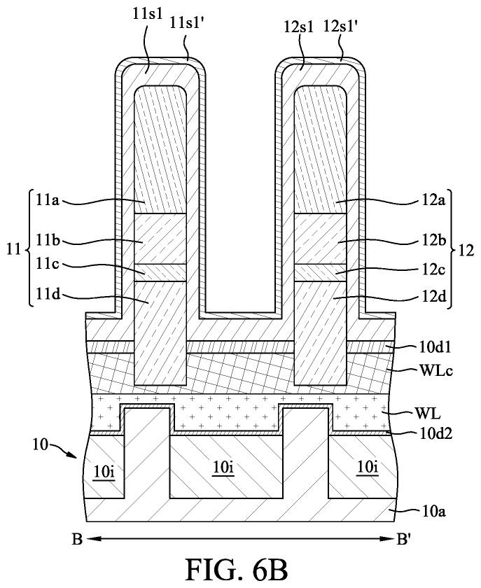

FIG. 6A and FIG. 6B illustrate operations subsequent to the operations in FIGS. 5A and 5B.

As shown in FIG. 6A and FIG. 6B, a surface treatment may be performed on the materials of the spacers 11s1 and 12s1 to change or modify surface properties of the materials of the spacers 11s1 and 12s1. For example, portions of the materials of the spacers 11s1 and 12s1 may be oxidized using oxygen plasma to enhance the etching rate of the surfaces of the materials of the spacers 11s1 and 12s1.

After the surface treatment, the treated materials, such as a treated material 11s1′ of the spacer 11s1 and a treated material 12s1′ of the spacer 12s1, may be formed.

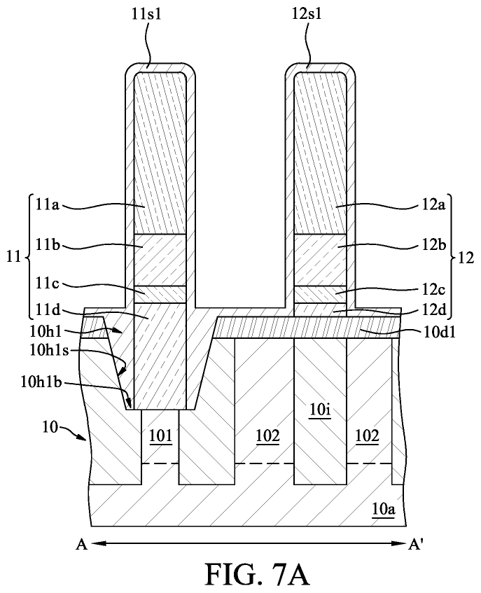

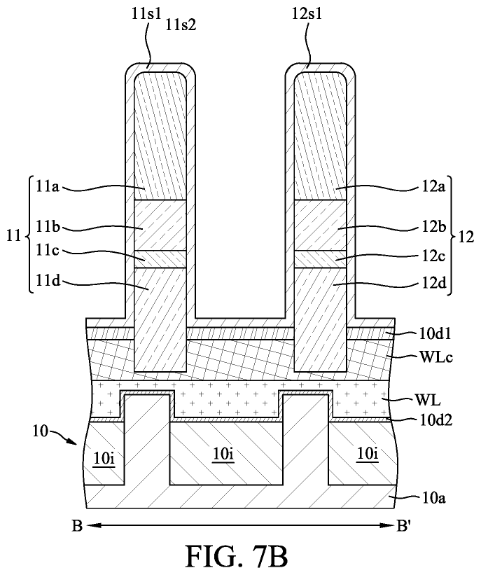

FIG. 7A and FIG. 7B illustrate operations subsequent to the operations in FIGS. 6A and 6B.

As shown in FIG. 7A and FIG. 7B, the treated materials, such as the treated material 11s1′ of the spacer 11s1 and the treated material 12s1′ of the spacer 12s1, may be removed using any suitable etching operation, such as wet etching. After the etching operation, a thickness of the material of the spacer 11s1 on the bit line structure 11 may range from approximately 5 nm to approximately 8 nm, and a thickness of the material of the spacer 12s1 on the bit line structure 12 may range from approximately 5 nm to approximately 8 nm.

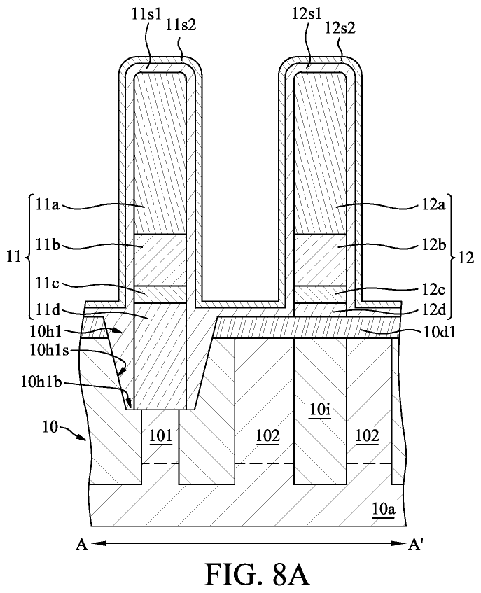

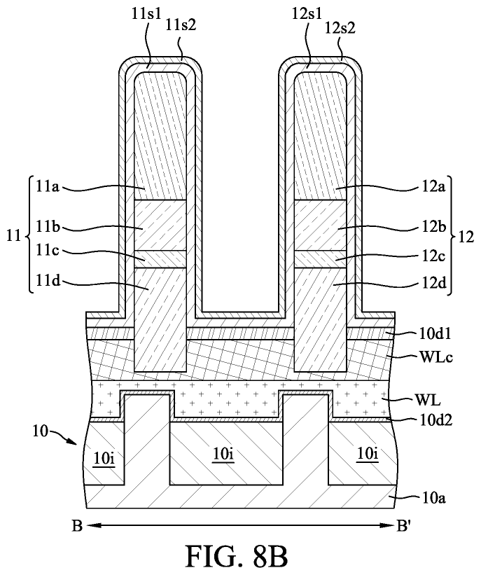

FIG. 8A and FIG. 8B illustrate operations subsequent to the operations in FIGS. 7A and 7B.

As shown in FIG. 8A and FIG. 8B, a material of spacer 11s2 may be formed on opposite sidewalls of the bit line structure 11. A material of the spacer 12s2 may be formed on opposite sidewalls of the bit line structure 12. In some embodiments, the spacers 11s2 and 12s2 may each include an oxygen-containing material, such as silicon oxide (SiO₂). In some embodiments, the materials of the spacers 11s2 and 12s2 may be formed using any suitable process, such as atomic layer deposition (ALD).

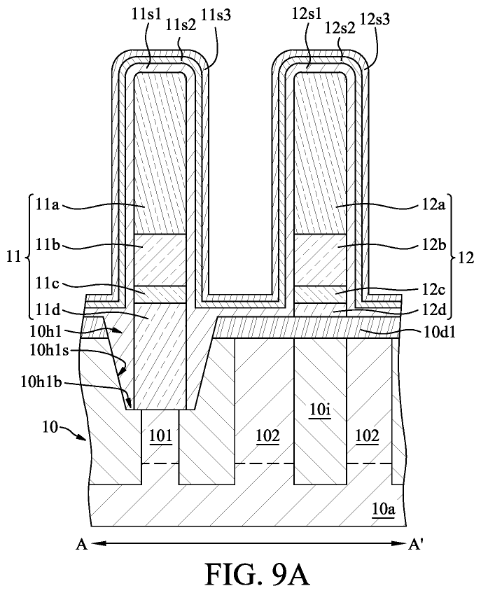

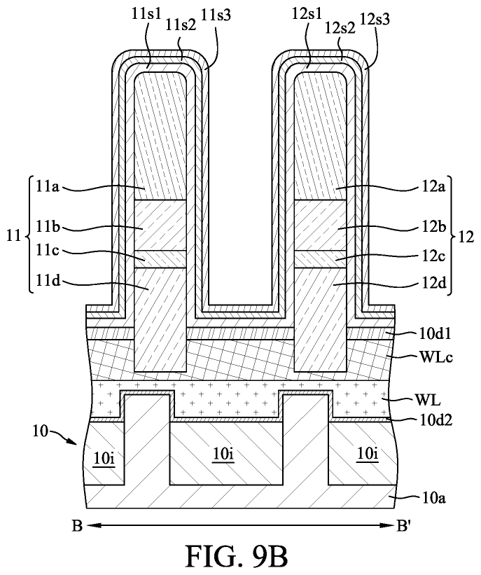

FIG. 9A and FIG. 9B illustrate operations subsequent to the operations in FIGS. 8A and 8B.

As shown in FIG. 9A and FIG. 9B, a material of spacer 11s3 may be formed on opposite sidewalls of the bit line structure 11. A material of the spacer 12s3 may be formed on opposite sidewalls of the bit line structure 12. In some embodiments, the spacers 11s3 and 12s3 may each include a nitrogen-containing material, such as silicon nitride (Si₃N₄). In some embodiments, the materials of the spacers 11s3 and 12s3 may be formed using any suitable process, such as atomic layer deposition (ALD).

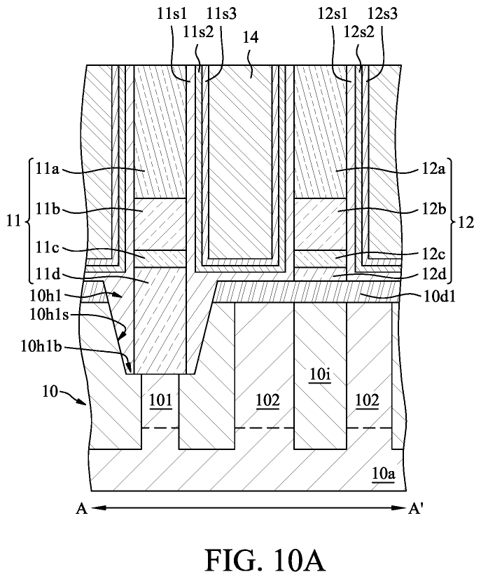

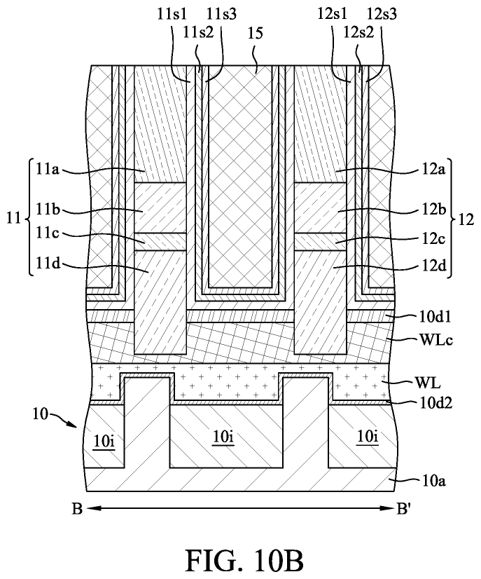

FIG. 10A and FIG. 10B illustrate operations subsequent to the operations in FIGS. 9A and 9B.

As shown in FIG. 10A, sacrificial patterns 14 may be formed among the plurality of bit line structures, such as the bit line structures 11 and 12). From a top view shown in FIG. 4A, the sacrificial patterns 14 may be spaced apart from each other in the second direction D2 and may be disposed between the word lines WL. The sacrificial patterns 14 may have an etching selectivity in accordance with the materials of the spacers 11s3 and 12s3. For example, the sacrificial patterns 14 may have an etching rate greater than etching rates of the materials of the spacers 11s3 and 12s3. For example, the sacrificial patterns 14 may be formed of a spin-on-hard mask (SOH) material (e.g., SOH silicon oxide).

As shown in FIG. 10B, insulating patterns 15 may be formed among the plurality of bit line structures, such as the bit line structures 11 and 12. From a top view shown in FIG. 4A, the insulating patterns 15 may fill a space defined by the plurality of bit line structures and the sacrificial patterns 14 and may overlap with the word lines WL. The insulating patterns 15 may include an insulating material having an etch selectivity in accordance with the sacrificial patterns 14. For example, the insulating patterns 15 may include, for example, silicon oxide (SiO₂), silicon nitride (Si₃N₄) and/or silicon oxynitride.

In some embodiments, sacrificial patterns 14 and insulating patterns 15 may be formed alternately and may be arranged along the second direction D2 between the bit line structures.

In some embodiments, the formation of the sacrificial patterns 14 and the insulating patterns 15 may include forming a material of the sacrificial patterns 14 to fill between the bit line structures, forming mask patterns (which may extend parallel to the word lines WL in the first direction D1) over the material of the sacrificial patterns 14, anisotropically etching the material of the sacrificial patterns 14 using the mask patterns and the bit line structures as an etch mask to form the sacrificial patterns 14 exposing the word lines WL, forming a material of the insulating patterns 15 to fill spaces between the sacrificial patterns 14 and between the bit line structures, and planarizing the material of the insulating patterns 15 to expose top surfaces of the mask patterns.

FIG. 11 illustrates operations subsequent to the operations in FIGS. 10A and 10B. FIG. 11 illustrates a cross-sectional view taken along line A-A′ of FIG. 4A.

As shown in FIG. 11, the sacrificial patterns 14 may be removed using a suitable etching operation, such as a directional or anisotropic dry etching operation. After the etching operation, the recess region 10h2 may be formed in the substrate 10 to expose the second doped region 102.

During the etching operation, the spacer 11s1 may protect the bit line contact 11d from being etched, consumed or damaged. Therefore, the spacer 11s1 may serve as a protection layer or a passivation layer for the bit line contact 11d.

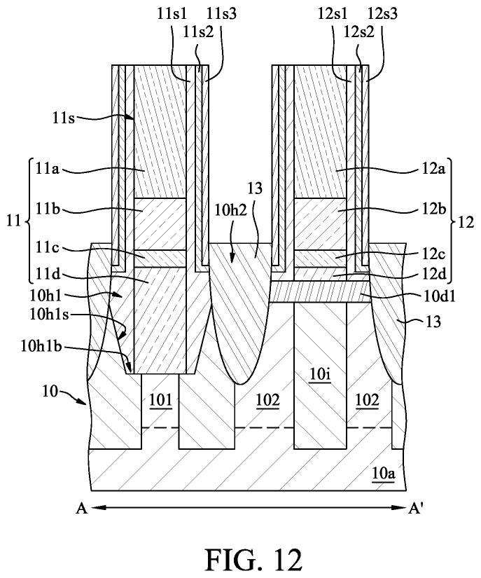

FIG. 12 illustrates operations subsequent to the operations in FIG. 11. FIG. 11 illustrates a cross-sectional view taken along line A-A′ of FIG. 4A.

As shown in FIG. 12, a material of the storage node contact 13 may be disposed in the recess region 10h2. The material of the storage node contact 13 may be disposed adjacent to the bit line structure 11. Subsequently, a recessing process may be performed on the material of the storage node contact 13. The recessing process may be performed using a dry etch process, such as an etch-back process.

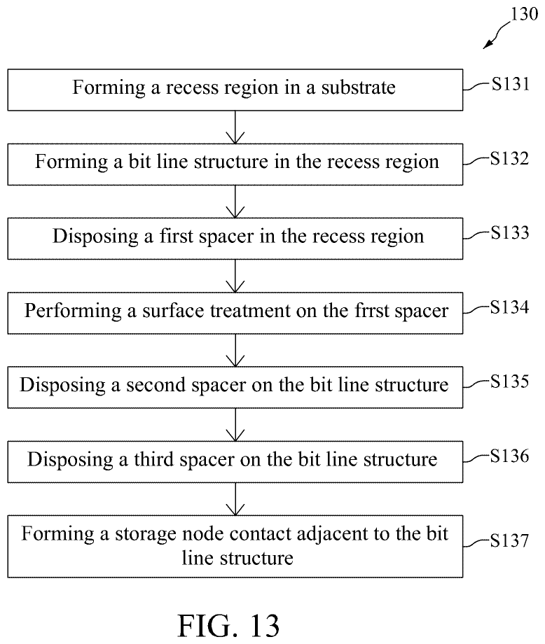

FIG. 13 illustrates a flowchart of a method 130 of manufacturing a semiconductor device in accordance with some embodiments of the present disclosure.

In some embodiments, the method 130 may include a step S131 of forming a recess region in a substrate. For example, as shown in FIG. 3A, the recess region 10h1 may be formed in the first doped region 101 between two word lines WL.

In some embodiments, the method 130 may include a step S132 of forming a bit line structure recess region in a substrate. For example, as shown in FIG. 4A, a plurality of bit line structures, such as the bit line structures 11 and 12, may be formed over the substrate 10.

In some embodiments, the method 130 may include a step S133 of disposing a first spacer in the recess region. For example, as shown in FIG. 5A, a material of the spacer 11s1 may be formed on opposite sidewalls 11s of the bit line structure 11. A material of the spacer 12s1 may be formed on opposite sidewalls 11s of the bit line structure 12. In some embodiments, the materials of the spacers 11s1 and 12s1 may fill the recess region 11h1 and conformally cover the bit line structures 11 and 12.

In some embodiments, the method 130 may include a step S134 of performing a surface treatment on the first spacer. For example, as shown in FIG. 6A, a surface treatment may be performed on the materials of the spacers 11s1 and 12s1 to change or modify the surface property of the materials of the spacers 11s1 and 12s1.

In some embodiments, the method 130 may include a step S135 of disposing a second spacer on the bit line structure. For example, as shown in FIG. 8A, a material of the spacer 11s2 may be formed on opposite sidewalls of the bit line structure 11. A material of the spacer 12s2 may be formed on opposite sidewalls of the bit line structure 12.

In some embodiments, the method 130 may include a step S136 of disposing a third spacer on the bit line structure. For example, as shown in FIG. 9A, a material of the spacer 11s3 may be formed on opposite sidewalls of the bit line structure 11. A material of the spacer 12s3 may be formed on opposite sidewalls of the bit line structure 12.

In some embodiments, the method 130 may include a step S137 of forming a storage node contact adjacent to the bit line structure. For example, as shown in FIG. 12, a material of the storage node contact 13 may be disposed in the recess region 10h2.

The formation of the semiconductor device 1d in FIG. 1D is similar to the formation of the semiconductor device 1a in FIG. 1A, except that the semiconductor device 1d includes the formation of an isolation structure 104 in the substrate 10. Some processes used to form the semiconductor device 1d are similar to, or same as, those used to form the semiconductor device 1a, and details thereof are not repeated.

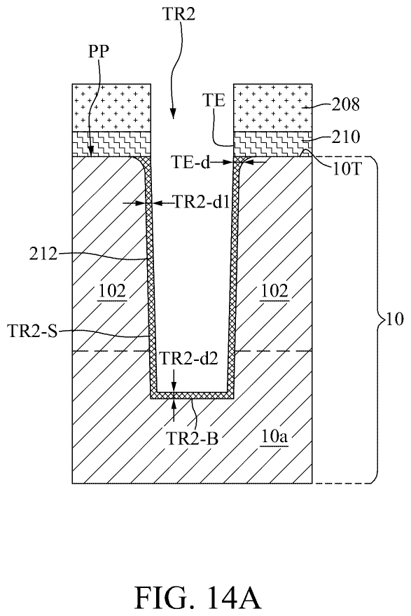

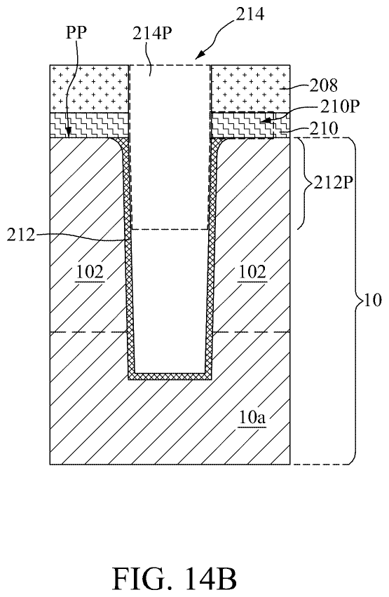

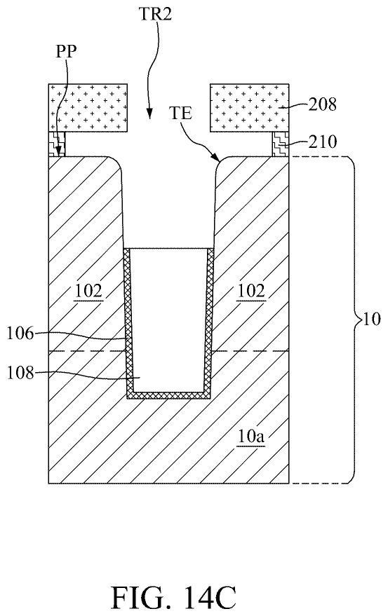

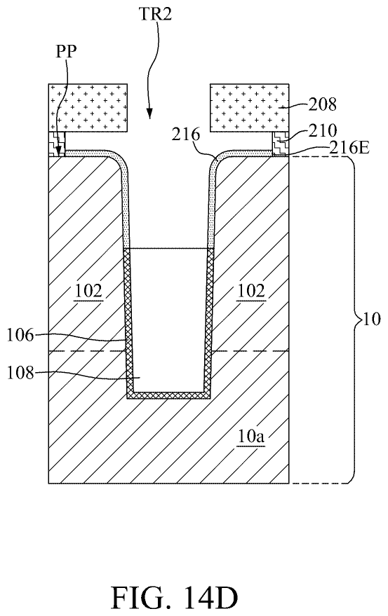

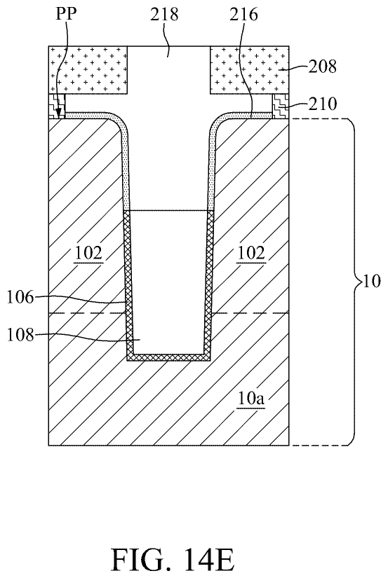

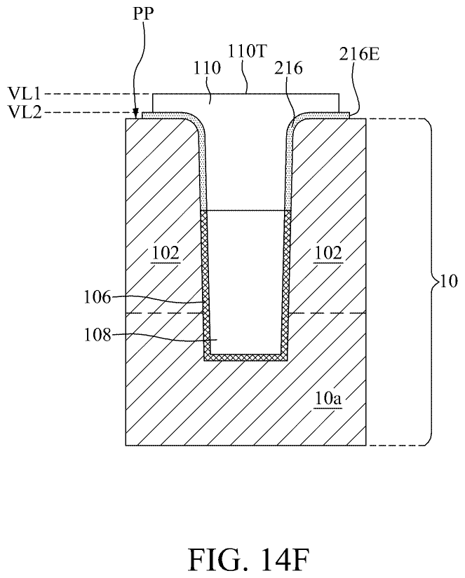

FIGS. 14A to 14E show schematic cross-sectional views illustrating the formation of the isolation structure 104 taken along a C-C′ line in FIG. 2A.

With reference to FIG. 14A, an assistance pattern 210 and a mask pattern 208 are sequentially disposed on the substrate 10. A trench TR2 may be formed in the substrate 10. The trench TR2 may have a bottom surface TR2-B and sidewalls TR2-S. In some embodiments, the trench TR2 may be formed through an opening defined by the assistance pattern 210 and the mask pattern 208. In some embodiments, the formation of the trench TR2 may also include performing an etching process, such as a dry etching process, a wet etching process, or a combination thereof, on a portion of the substrate 10 exposed by the opening.

Subsequently, an oxidation process is performed. During the oxidation process, the substrate 10 is oxidized from the surfaces exposed in the trench TR2, and portions of the substrate 10 subjected to oxidation turn into an oxide layer 212. The oxide layer 212 extends along the sidewalls TR2-S, as well as the bottom surface TR2-B of the trench TR2. As shown in FIG. 14A, a top edge oxidation depth TE-d (i.e., a thickness of the oxide layer 212 near a top edge TE of the active area 10a) is greater than a sidewall oxidation depth TR2-d1 at the sidewall TR2-S of the trench TR2 and a bottom oxidation depth TR2-d2 at the bottom surface of the trench TR2. In some embodiments, the oxidation process encroaches upon the active area 10a, forming rounded or chamfered top edge TE.

With reference to FIG. 14B, an insulating structure 214 is filled in the trench TR2. The insulating structure 214 may be further thinned in a subsequent step to form a lower insulating structure 108 as described with reference to FIG. 14C. Since the oxide layer 212 extends along the bottom surface TR2-B and the sidewall TR2-S of the trench TR2, the substrate 10 can be separated from the insulating structure 214 by the oxide layer 212. In some embodiments, the insulating structure 214 fills the trench TR2. In some embodiments, in addition to surfaces of the oxide layer 212 defining a bottom surface and sidewalls of the trench TR2, sidewall of the mask pattern 208 and the assistance pattern 210 are also in lateral contact with the insulating structure 214. Further, a top surface of the insulating structure 214 may be substantially coplanar with a top surface of the mask pattern 208. A method for preparing the insulating structure 214 may include providing an insulating material on the structure shown in FIG. 14A using a deposition process, such as a CVD process. Subsequently, portions of the insulating material above the top surface of the mask pattern 208 may be removed by a planarization process, and the remaining portion of the insulating material in the trench TR2 forms the insulating structure 214. For example, the planarization process may include a polishing process, an etching process, or a combination thereof.

With reference to FIG. 14C, the insulating structure 214, the oxide layer 212, and the assistance pattern 210 are partially removed. A top portion 214P of the insulating structure 214, as shown in FIG. 14B, is removed, and the insulating structure 214 is thinned accordingly to form a lower insulating structure 108. Along with the removal of the top portion 214P of the insulating structure 214, a portion of the oxide layer 212 covering the top edge TE of the active area 10a may be also removed, and the remaining portion of the oxide layer 212 form a lining layer 106. Further, the assistance pattern 210 may be laterally recessed from the sidewall TR2-S of the trench TR2 during the partial removal of the insulating structure 214 and the oxide layer 212. By laterally recessing the assistance pattern 210, the top edge TE of the active area 10a may be exposed. In some embodiments, a method for partially removing the insulating structure 214, the oxide layer 212, and the assistance pattern 210 includes an isotropic etching process. The substrate 100 and the mask pattern 208 may have sufficient etching selectivity relative to the insulating structure 214 and the oxide layer 212; thus, the substrate 100 and the mask pattern 208 may be barely etched during such an isotropic etching process. Further, the thickness of the lower insulating structure 108 and a height of the lining layer 106 can be determined by a process time of the isotropic etching.

With reference to FIG. 14D, an epitaxial layer 216 is formed. The epitaxial layer 216 is selectively formed on the exposed top edge TE of the active area 10a and thus may not extend along exposed surfaces of the lower insulating structure 108, the assistance pattern 210 and the mask pattern 208. Further, the top edge TE of the active area 10a may be conformally covered with the epitaxial layer 216. In some embodiments, a topmost end 216E of the epitaxial layer 216 is slightly higher than a topmost surface of the substrate 10 (i.e., the planar part PP of the active area 10a). The epitaxial layer 216 is formed by an epitaxial process. During the epitaxial process, the epitaxial layer 216 may selectively grow from exposed surface of the substrate 10 (i.e., the top edge TE of the active area 10a), and the epitaxial process may be referred to as a selective epitaxial process.

With reference to FIG. 14E, an insulating structure 218 is formed. The insulating structure 218 may be further shaped in the following steps to form an upper insulating structure 110 as shown in FIG. 1D. During the formation of the insulating structure 218, the trench TR2 is currently filled, and the insulating structure 218 may cover a top surface of the lower insulating structure 108 and may be in lateral contact with the epitaxial layer 216. Further, spaces defined between the active area 10a and the mask pattern 208 may be filled with the insulating structure 218. Accordingly, portions of the epitaxial layer 216 extending into these spaces may be covered with the insulating structure 218, and the assistance pattern 210 may be in lateral contact with the insulating structure 218. In addition, the extending portions of the insulating structure 218 may be in contact with the mask pattern 208 from below. In some embodiments, a top surface of the insulating structure 218 is substantially coplanar with top surfaces of the mask pattern 208. A method for preparing the insulating structure 218 may include providing an insulating material on the structure shown in FIG. 14D using a deposition process, such as a CVD process. Subsequently, a portion of the insulating material above the top surface of the mask pattern 208 is removed by a planarization process. For example, the planarization process may include a polishing process, an etching process or a combination thereof.

With reference to FIG. 14F, the mask pattern 208 and the assistance pattern 210 are removed. By removing the mask pattern 208 and the assistance pattern 210, the topmost surface of the substrate 10 (i.e., the planar part PP of the active area 10a) and portions of the insulating structure 218 that were covered by the mask pattern 208 and the assistance pattern 210 may now be exposed. Subsequently, a thinning process, such as chemical mechanical polishing, may be subsequently performed until a uniform top surface (e.g., the top surface 110T) of the upper insulating structure 110 is formed, providing a substantially flat surface for subsequent processing steps and concurrently form the upper insulating structure 110. The top surface 110T of the upper insulating structure 110 may at a vertical position VL1 higher than a vertical position VL2 of the topmost end 216E of the epitaxial layer 216. A method for removing the mask pattern 208 and the assistance pattern 210 may include an isotropic etching process. Since the assistance pattern 210 may have sufficient etching selectivity relative to the mask pattern 208, allowing multiple steps of the etching process to be performed to remove the mask pattern 208 and the assistance pattern 210. In some embodiments, a method for thinning the insulating structure 218 may include a polishing process, an etching process, or a combination thereof.

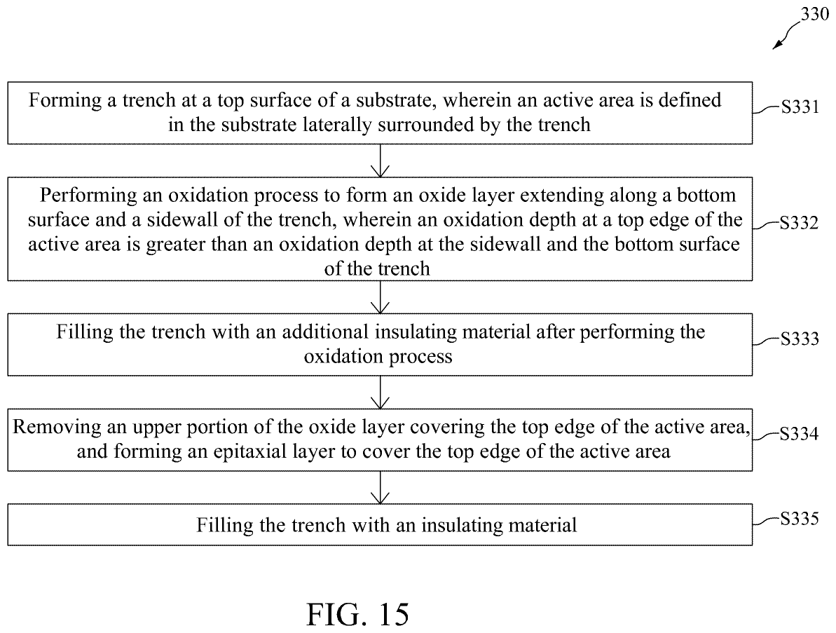

FIG. 15 illustrates a flowchart diagram of a method 330 of manufacturing an isolation structure of a semiconductor device in accordance with various embodiments of the present disclosure.

In some embodiments, the method 330 may include a step S331 of forming a trench at a top surface of a substrate. An active area is defined in the substrate laterally surrounded by the trench. For example, as shown in FIG. 14A, the trench TR2 may be formed at the top surface 10T of the substrate 10. The active area 10a may be defined in the substrate 10 laterally surrounded by the trench TR2.

In some embodiments, the method 330 may include a step S332 of performing an oxidation process to form an oxide layer extending along a bottom surface and a sidewall of the trench. An oxidation depth at a top edge of the active area is greater than an oxidation depth at the sidewall and the bottom surface of the trench. For example, as shown in FIG. 14A, the oxide layer 212 may be formed extending along the bottom surface TR2-B and the sidewall TR2-S of the trench TR2. The top edge oxidation depth TE-d (the oxidation depth at the top edge TE of the active area 10a) is greater than the sidewall oxidation depth TR2-d1 at the sidewall TR2-S of the trench TR2 and the bottom oxidation depth TR2-d2 at the bottom surface TR2-B of the trench TR2.

In some embodiments, the method 330 may include a step S333 of filling the trench with an additional insulating material after performing the oxidation process. For example, as shown in FIG. 14B, the insulating structure 214 may be filled in the trench TR2.

In some embodiments, the method 330 may include a step S334 of removing an upper portion of the oxide layer covering the top edge of the active area, and forming an epitaxial layer to cover the top edges of the active area. For example, as shown in FIGS. 14B, 14C and 14D, the upper portion 212P of the oxide layer 212 covering the top edge TE of the active area 10a may be removed. The epitaxial layer 216 may be formed to cover the top edge TE of the active area 10.

In some embodiments, the method 330 may include a step S335 of filling the trench with an insulating material. For example, as shown in FIG. 14E, the trench TR2 may be filled with the insulating structure 218.

The formation of the semiconductor device 1e in FIG. 1E is similar to the formation of the semiconductor device 1a in FIG. 1A, except that the semiconductor device 1e includes the formation of air gaps 113 and 123. Some processes used to form the semiconductor device 1e are similar to, or same as, those used to form the semiconductor device 1a, and details thereof are not repeated.

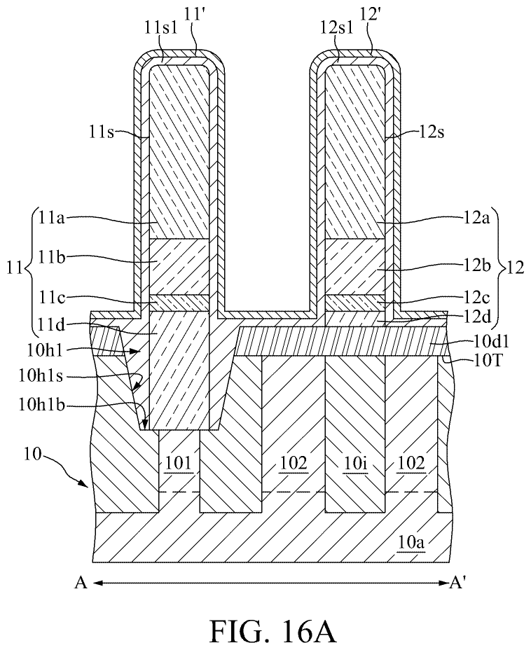

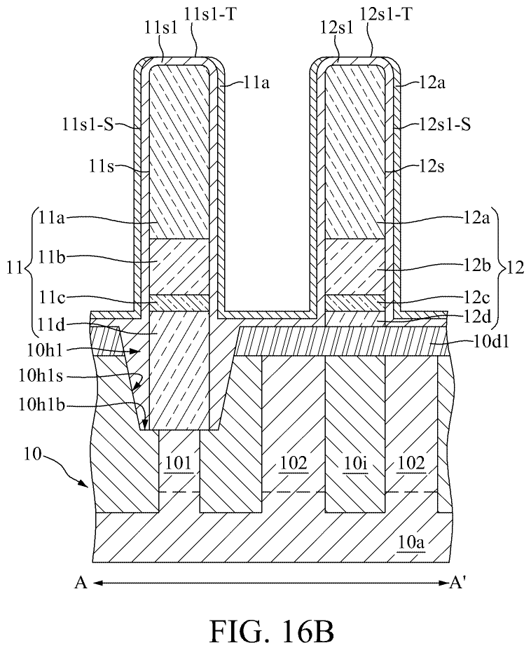

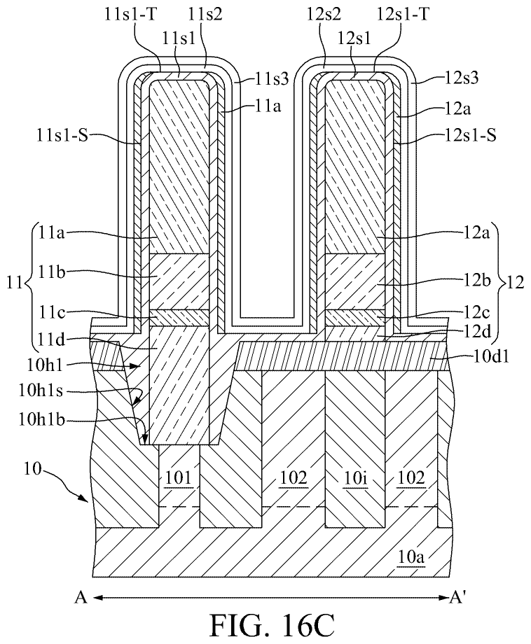

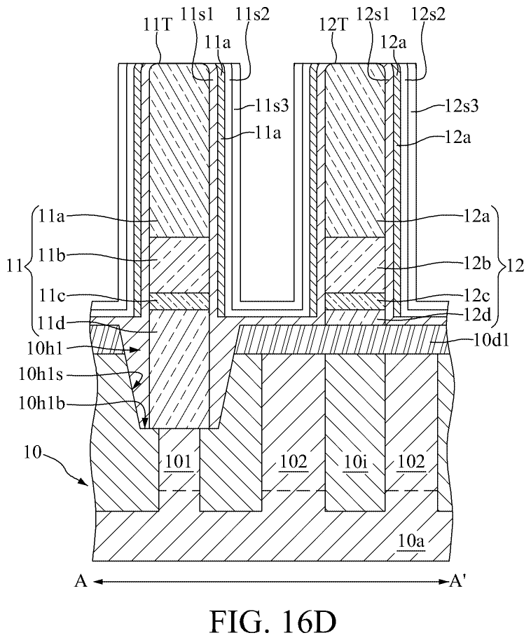

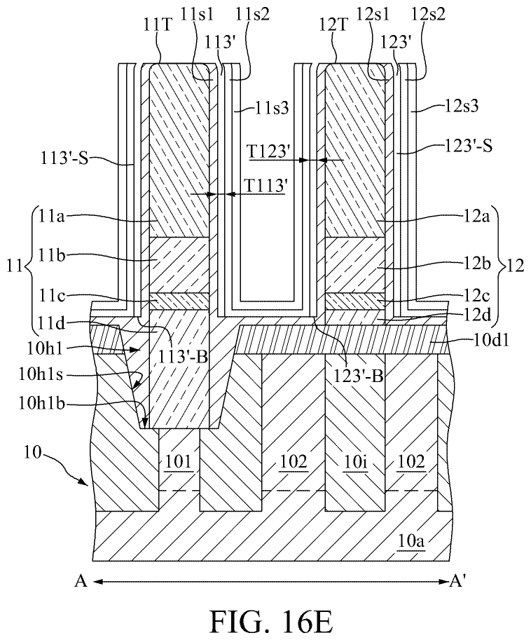

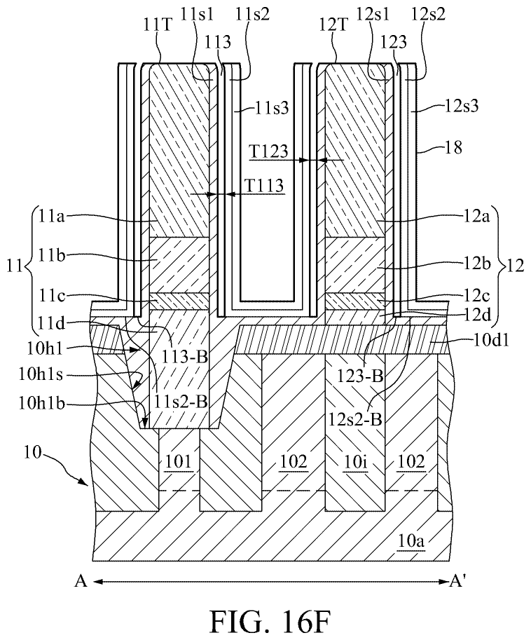

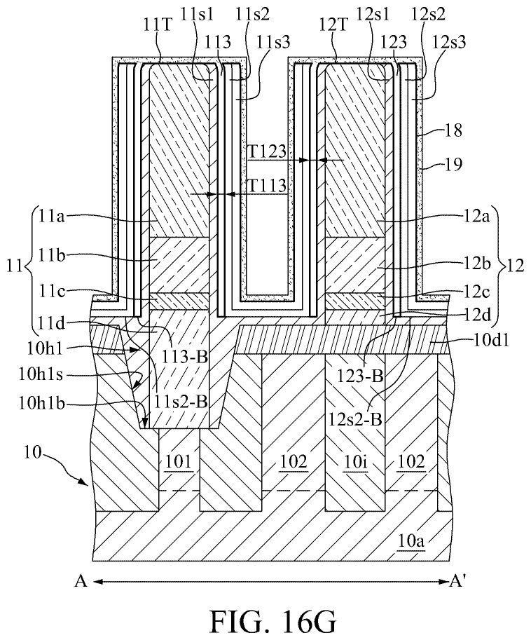

FIGS. 16A to 16G show schematic cross-sectional views illustrating the formation of air gaps 113 and 123 taken along a line A-A′ in FIG. 2A in accordance with various embodiments of the present disclosure. The operations illustrated in FIGS. 16A to 16G may be performed after the formation of the spacers 11s1 and 12s1 illustrated in FIGS. 7A and 7B, and prior to the formation of the sacrificial patterns 14 and 15 as shown in FIGS. 10A and 10B.

With reference to FIG. 16A, a layer of sacrificial material 11′ may be conformally deposited on the spacer 11s1 and the substrate 10. In some embodiments, a thicknesses of the layer of sacrificial material 11′ may be in a range of 2 to 5 nanometers. In some embodiments, the layer of sacrificial material 11′ may be formed by deposition process, such as a chemical vapor deposition.

Similarly, a layer of sacrificial material 12′ may be conformally deposited on the spacer 12s1 and the substrate 10. In some embodiments, a thicknesses of the layer of sacrificial material 12′ may be in a range of 2 to 5 nanometers. In some embodiments, the layer of sacrificial material 11′ may be formed by a deposition process, such as chemical vapor deposition.

With reference to FIG. 16B, subsequently, a removing process, such as an etching process, is performed to remove horizontal portions of the layer of sacrificial material 11′ and the layer of sacrificial material 12′ over a top surface 11s1-T of the spacer 11s1 and over a top surface 11s2-T of the spacer 11s2, respectively, and to remove horizontal portions on the substrate 10. Therefore, a sacrificial layer 11a may be formed on a sidewall 11s1-S, and a sacrificial layer 12a may be formed on a sidewall 12s1-S.

With reference to FIG. 16C, a layer of spacer 11s2 may be formed on opposite sidewalls of the bit line structure 11. A layer of the spacer 12s2 may be formed on opposite sidewalls of the bit line structure 12. In some embodiments, the spacers 11s2 and 12s2 may each include an oxygen-containing material, such as silicon oxide (SiO₂). In some embodiments, the layer of spacer 11s2 and the layer of spacer 12s2 may be formed using any suitable process, such as atomic layer deposition (ALD).

Sequentially, a layer of spacer 11s3 may be formed on opposite sidewalls of the bit line structure 11. A layer of the spacer 12s3 may be formed on opposite sidewalls of the bit line structure 12. In some embodiments, the spacers 11s3 and 12s3 may each include a nitrogen-containing material, such as silicon nitride (Si₃N₄). In some embodiments, the layer of spacer 11s3 and the layer of spacer 12s3 may be formed using any suitable process, such as atomic layer deposition (ALD).

With reference to FIG. 16D, a planarization process may be performed to remove portions of the layers of spacer 11s1, 11s2, 11s3 and the sacrificial layer 11a over a top surface 11T of the bit line structure 11, and to remove portions of the layers of spacers 12s1, 12s2, 12s3 and the sacrificial layer 12a over a top surface 12T of the bit line structure 12. In some embodiments, the planarization process may be performed by an etching process, such as a dry etching process. After the planarization process, top surfaces of the spacers 11s1, 11s2, 11s3 and the sacrificial layer 11a may be coplanar with the top surface 11T of the bit line structure 11, and top surfaces of the spacers 12s1, 12s2, 12s3 and the sacrificial layer 12a may be coplanar with the top surface 12T of the bit line structure 11. It should be noted that the top surface 11T of the bit line structure 11 may be substantially aligned with the top surface 12T of the bit line structure 12.

With reference to FIG. 16E, the sacrificial layer 11a is removed, thereby forming a gap 113′ between the spacer 11s1 and the spacer 11s2. In some embodiments, the sacrificial layer 11a is removed using a vapor etching operation. In some embodiments, vapor-phase hydrogen fluoride (HF) is used to remove the sacrificial layer 11a. In some embodiments, the gap 113′ has a width T113′ in a range of 5 to 8 nanometers, which is equal to a distance between a vertical portion of the spacer 11s1 and the spacer 11s2. In some embodiments, the width T113′ of the gap 113′ is substantially equal to a thickness of the sacrificial layer 11a.

The sacrificial layer 12a is removed, thereby forming a gap 123′ between the spacer 12s1 and the spacer 12s2. In some embodiments, the sacrificial layer 12a is removed by a vapor etching operation. In some embodiments, vapor-phase hydrogen fluoride (HF) is used to remove the sacrificial layer 12a. In some embodiments, the gap 123′ has a width T123′ in a range of 5 to 8 nanometers, which is equal to a distance between a vertical portion of the spacer 12s1 and the spacer 12s2. In some embodiments, the width T123′ of the gap 123′ is substantially equal to a thickness of the sacrificial layer 11a.

With reference to FIG. 16F, a spacer layer 18 is formed along an inner sidewall 113′-S and a bottom surface 113′-B of the air gap 113′, resulting in a reduction of the width T113′ of the gap 113′. In addition, the spacer layer 18 may further be formed lining the spacer 11s3 and on top surfaces of the bit line structure 11 and the spacers 11s1 and 11s2. In some embodiments, the spacer layer 18 is formed by an atomic layer deposition. The spacer layer 18 is made of dielectric materials. In some embodiments, the spacer layer 18 includes nitride, oxide, oxynitride, or a combination thereof. In some embodiments, the spacer layer 18 is made of a material same as a material of the spacer 11s1 or the spacer 11s2. In some embodiments, there is no distinct interface between the spacer layer 18 and the spacer 11s1 if the spacer layer 18 and the spacer 11s1 are made of the same material. In some embodiments, there is no distinct interface between the spacer layer 18 and the spacer 11s2 if the spacer layer 18 and the spacer 11s2 are made of the same material. In some embodiments, a thickness of the spacer layer 18 is in a range of 0.5 to 2 nanometers.

Similarly, the spacer layer 18 is also formed along an inner sidewall 123′-S and a bottom surface 123′-B of the air gap 123′, resulting in a reduction of the width T123′ of the gap 123′. In addition, the spacer layer 18 may further be formed lining the spacer 12s3 and on top surfaces of the bit line structure 12 and the spacers 12s1 and 12s2. In some embodiments, the spacer layer 18 is made of a material same as a material of the spacer 12s1 or the spacer 12s2. In some embodiments, there is no distinct interface between the spacer layer 18 and the spacer 12s1 if the spacer layer 18 and the spacer 12s1 are made of the same material. In some embodiments, there is no distinct interface between the spacer layer 18 and the spacer 12s2 if the spacer layer 18 and the spacer 12s2 are made of the same material.

After the formation of the spacer layer 18, a gap 113 is formed. The gap 113 is formed from the gap 113′ and has a width T113 controlled in a range of 3 to 5 nanometers. In some embodiments, the width T113 is less than the width T113′ by 1 to 4 nanometers.

Accordingly, after the formation of the spacer layer 18, a gap 123 is also formed. The gap 123 is formed from the gap 123′ and has a width T123 controlled in a range of 3 to 5 nanometers. In some embodiments, the width T123 is less than the width T123′ by 1 to 4 nanometers.

With reference to FIG. 16G, a seal layer 19 is formed over the spacer layer 18 and sealing the air gaps 113 and 123. In some embodiments, the seal layer 19 is conformal to a profile of the bit line structures 11 and 12. In some embodiments, the seal layer 19 is formed using a chemical vapor deposition (CVD), which seals the air gaps 113 and 123 without filling in the gaps 113 and 123. In some embodiments, the seal layer 19 is formed with a high deposition rate so that to have a less condensed structure and prevent filling in the gaps 113 and 123.

After the formation of the seal layer 9, followed by the operations illustrated in FIGS. 10A, 11, and 12, the semiconductor device 1e shown in FIG. 1E can be obtained.

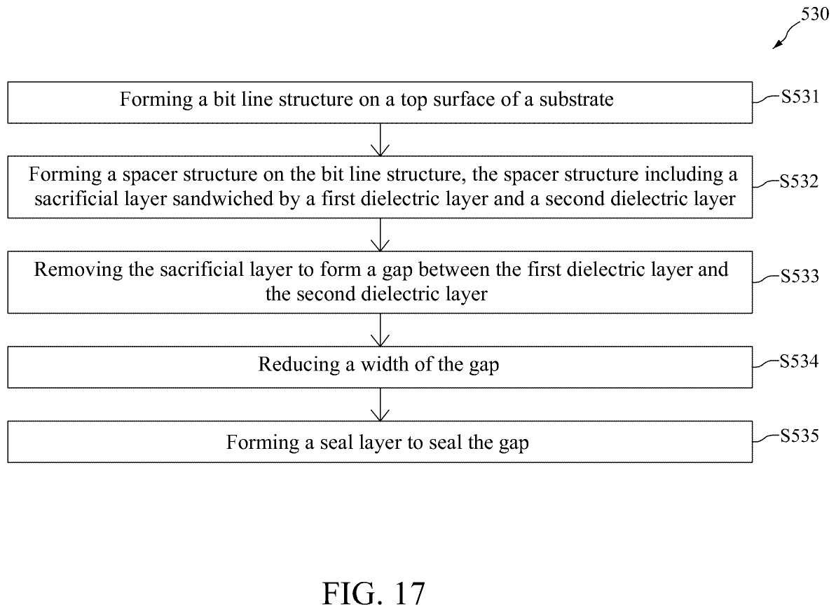

FIG. 17 illustrates a flowchart diagram of a method 530 of manufacturing an air gap of a semiconductor device in accordance with various embodiments of the present disclosure.

In some embodiments, the method 530 may include a step S531 of forming a bit line structure on a top surface of the substrate. For example, as shown in FIG. 16A, a bit line structure 11 may be formed on the top surface 10T of the substrate 10.

In some embodiments, the method 530 may include a step S532 of forming a spacer structure on the bit line structure, the spacer structure including a sacrificial layer sandwiched by a first dielectric layer and a second dielectric layer. For example, as shown in FIG. 16D, the spacers 11s1, 11s2, 11s3, and the sacrificial layer 11a may be formed on the bit line structure 11. The spacers 11s1, 11s2, 11s3, and the sacrificial layer 11a may together form the spacer structure. The spacer structure includes the sacrificial layer 11a sandwiched by the spacer 11s1 and the spacer 11s2.

In some embodiments, the method 530 may include a step S533 of removing the sacrificial layer to form a gap between the first dielectric layer and the second dielectric layer. For example, as shown in FIG. 16E, the sacrificial layer 11a may be removed to form the air gap 113′ between the spacer 11s1 and the spacer 11s2.

In some embodiments, the method 530 may include a step S534 of reducing a width of the gap. For example, as shown in FIG. 16F, the width T113 of the air gap 113 is less than the width T113′ of the air gap 113′ in FIG. 16E after the spacer layer 18 is formed lining the air gap 113′.

In some embodiments, the method 530 may include a step S535 of forming a seal layer to seal the gap. For example, as shown in FIG. 16G, the seal layer 19 may be formed to deal the air gap 113.

One aspect of the present disclosure provides a semiconductor device. The semiconductor device includes a substrate having a first recess region; a first bit line structure disposed in the first recess region; and an isolation structure disposed within a trench in the substrate. The first bit line structure has a first spacer, a second spacer, and a third spacer. The isolation structure includes a lining layer, an epitaxial layer, a lower insulating structure, and an upper insulating structure.

Another aspect of the present disclosure provides a semiconductor device. The semiconductor device includes a substrate having a first recess region; and a first bit line structure disposed in the first recess region. The first bit line structure has a first spacer, an air gap, a second spacer, and a third spacer. The first spacer, the second spacer, and the third spacer have different materials.

Another aspect of the present disclosure provides a method for fabricating a semiconductor device. The method includes forming a trench at a top surface of a substrate, wherein an active area is defined in the substrate laterally surrounded by the trench; performing an oxidation process to form an oxide layer extending along a bottom surface and a sidewall of the trench, wherein an oxidation depth at a top edge of the active area is greater than an oxidation depth at the sidewall and the bottom surface of the trench; filling the trench with an additional insulating material after performing the oxidation process; removing an upper portion of the oxide layer covering the top edge of the active area, and forming an epitaxial layer to cover the top edge of the active area; and filling the trench with an insulating material.

Another aspect of the present disclosure provides a method for fabricating a semiconductor device. The method includes forming a bit line structure on a top surface of a substrate; forming a spacer structure on the bit line structure, the spacer structure including a sacrificial layer sandwiched by a first dielectric layer and a second dielectric layer; removing the sacrificial layer to form a gap between the first dielectric layer and the second dielectric layer; reducing a width of the gap; and forming a seal layer to seal the gap.

The first spacer can prevent the first bit line structure from being damaged or consumed. Therefore, the bit line structure to storage node contact leakage issue can be addressed. The performance and operational reliability of the semiconductor device can also be improved.

In addition, by using a spacer having a low dielectric constant, the parasitic capacitance issue between the bit line structures and/or between the bit line structure and the storage node contact can be further reduced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate having a first recess region;
a first bit line structure disposed in the first recess region; and
an isolation structure disposed within a trench in the substrate;
wherein the first bit line structure has a first spacer, a second spacer, and a third spacer, and
wherein the isolation structure includes a lining layer, an epitaxial layer, a lower insulating structure, and an upper insulating structure.

2. The semiconductor device of claim 1, wherein the first spacer, the second spacer, and the third spacer have different materials.

3. The semiconductor device of claim 1, wherein the lining layer is in contact with the epitaxial layer from below the epitaxial layer.

4. The semiconductor device of claim 1, wherein the lining layer is formed of silicon oxide.

5. The semiconductor device of claim 1, wherein the epitaxial layer is conformally disposed on an upper sidewall of the trench and on a top edge of the substrate.

6. The semiconductor device of claim 5, wherein a topmost end of the epitaxial layer is higher than a topmost surface of the substrate.

7. The semiconductor device of claim 1, wherein the epitaxial layer is formed using an epitaxial process.

8. The semiconductor device of claim 1, wherein the lower insulating structure is disposed in a lower part of the trench.

9. The semiconductor device of claim 8, wherein a height of the lower insulating structure is substantially leveled with a topmost end of the lining layer.

10. The semiconductor device of claim 1, wherein the upper insulating structure is disposed in an upper part of the trench and in lateral contact with the epitaxial layer.

11. The semiconductor device of claim 6, wherein the upper insulating structure extends from a top surface of the lower insulating structure to a height higher than the topmost end of the epitaxial layer.

12. A semiconductor device, comprising:
a substrate having a first recess region; and
a first bit line structure disposed in the first recess region;
wherein the first bit line structure has a first spacer, an air gap, a second spacer, and a third spacer, and
wherein the first spacer, the second spacer, and the third spacer have different materials.

13. The semiconductor device of claim 12, wherein the first bit line structure contacts a first doped region in the substrate.

14. The semiconductor device of claim 12, wherein a sidewall of the first recess region is inclined relative to the substrate.

15. The semiconductor device of claim 12, wherein the first spacer includes a carbon-containing material.

16. The semiconductor device of claim 12, wherein the second spacer is disposed between the first spacer and the third spacer, and a first dielectric constant of the first spacer is less than a second dielectric constant of the second spacer.

17. The semiconductor device of claim 12, wherein the air gap is disposed between the first spacer and the second spacer.

18. The semiconductor device of claim 17, wherein the air gap is sealed by a seal layer.

19. The semiconductor device of claim 18, wherein a bottom surface of the air gap is coplanar with a bottom surface of the second spacer.

20. The semiconductor device of claim 19, wherein the bottom surface and a sidewall of the air gap are covered by a spacer layer.
